(19) United States
(12) Patent Application Publication
(10) Pub. No.: US 2018/0158380 A1
(43) Pub. Date: Jun. 7, 2018

(54) FLUORESCENT CONCENTRATOR SOLAR CELL

(71) Applicant: SHARP KABUSHIKI KAISHA, Sakai City, Osaka (JP)

(72) Inventors: Satoshi SHIBATA, Sakai City (JP); Tomohisa YOSHIE, Sakai City (JP); Shunpei YAMANAKA, Sakai City (JP); Ryohsuke YAMANAKA, Sakai City (JP)

(21) Appl. No.: 15/569,973

(22) PCT Filed: Dec. 1, 2015
(86) PCT No.: PCT/JP2015/083780

§ 371 Date: Oct. 27, 2017

(30) Foreign Application Priority Data
Apr. 27, 2015 (JP) 2015-090807

(51) Int. Cl. G09F 13/20; H01L 31/055; H02S 99/00; H01L 31/054

(52) U.S. Cl. CPC G09F 13/20; H01L 31/0547; H02S 99/00; H01L 31/055

(57) ABSTRACT

A high visual effect is achieved while variation in electric current values among solar cells is suppressed. A fluorescent concentrating plate (2) provided in a fluorescent concentrator solar cell (11) according to an aspect of the invention includes a display portion (3) that includes a peripheral end surface (31) which emits a part of guided light to an outside to thereby perform light emission and a base portion (4) that includes an upper end surface (41) supporting the display portion (3), and a lower end surface (42) and side end surfaces (43 and 44) on which a solar cell array (5) is arranged.

### TECHNICAL FIELD

The present invention relates to a solar cell, and, more specifically, relates to a fluorescent concentrator solar cell provided with a fluorescent concentrating plate that includes a phosphor.

### BACKGROUND ART

A solar cell is considered to be important as a clean energy source, and demand therefor is increasing year after year. A field of application of the solar cell widely ranges from a power energy source for large-sized equipment or the like to a small-sized power source for precision electronic equipment or the like, and various photovoltaic power generation devices each including a solar cell are widely spreading.

In accordance with the spread of the solar cell, use of the solar cell is also expanding. For example, PTL 1 proposes a solar cell that displays a pattern such as a letter, a figure, or a symbol on a part of a light-receiving surface (light incident surface). The solar cell displays a pattern on a part of the light-receiving surface by arranging scattering materials or the like, whose hazes are different, on the light-receiving surface of the solar cell.

Moreover, PTL 2 proposes a solar cell in which a plurality of solar cells a rectangular shape of each of which is arranged so that a longitudinal direction of each of the solar cells is oriented in a vertical direction of a vehicle are connected in a lateral direction. The solar cell aims to equalize light quantity distribution of light incident on the solar cells by connecting, in series in the lateral direction, the solar cells the rectangular shape of each of which is arranged so that the longitudinal direction is oriented in the vertical direction.

Furthermore, PTL 3 proposes a fluorescent concentrator solar cell which is provided with a fluorescent concentrating plate including a phosphor, converts light incident from a light-receiving surface of the fluorescent concentrating plate into fluorescent light, and concentrates the fluorescent light to a solar cell arranged on a part of an end surface of the fluorescent concentrating plate. The fluorescent concentrator solar cell increases light quantity to be concentrated to the solar cell and improves efficiency of power generation by providing a reflecting plate on an end surface of the fluorescent concentrating plate, on which the solar cell is not arranged.

### CITATION LIST

### Patent Literature

PTL 1: Japanese Unexamined Patent Application Publication No. 2001-257375 (published on Sep. 21, 2001)
PTL 2: Japanese Unexamined Patent Application Publication No. 2014-236130 (published on Dec. 15, 2014)
PTL 3: International Publication No. 2011/158548 (published on Dec. 22, 2011)

### SUMMARY OF INVENTION

### Technical Problem

However, a technique of PTL 1 enables only causing a pattern such as a letter, a figure, or a symbol to uniformly emit light to be displayed on a part of the light-receiving surface, so that there is a problem that a visual effect is not achieved enough. Moreover, incident light is shut out by the pattern formed on the part of the light-receiving surface, and therefore light receiving quantity becomes ununiform among solar cells arranged directly under the light-receiving surface, so that there is a problem that variation in electric current values generated by the solar cells is easily caused.

Moreover, with a technique of PTL 2, it is possible to achieve equalization of light quantity distribution with respect to light quantity distribution generated in a longitudinal direction of each solar cell, but it is difficult to achieve equalization of light quantity distribution with respect to light quantity distribution generated in a lateral direction of each solar cell. Accordingly, there is a problem that variation in electric current values generated by the solar cells is easily caused. In a case of connecting the solar cells among which variation in electric current values is caused in series, the electric current values are controlled by a solar cell having a low electric current, so that power generation quantity which is able to be taken out from the entire solar cell becomes small, resulting in that great power loss is caused.

Furthermore, a technique of PTL 3 aims to improve the efficiency of power generation of the fluorescent concentrator solar cell, and does not have a configuration for displaying a letter, a figure, a symbol, or the like by using a fluorescent concentrating plate in order to obtain a visual effect.

The invention is made in view of the aforementioned problems, and an object thereof is to provide a fluorescent concentrator solar cell by which a high visual effect which has not achieved before is obtained by using a fluorescent concentrating plate while suppressing variation in electric current values among solar cells.

### Solution to Problem

In order to solve the aforementioned problems, a fluorescent concentrator solar cell according to an aspect of the invention includes: a fluorescent concentrating plate that includes a phosphor converting a wavelength of received light and guides the light; and a solar cell that includes a plurality of solar cells each of which receives the light guided by the fluorescent concentrating plate, in which the fluorescent concentrating plate includes a display portion that includes a first end surface which emits a part of the guided light to an outside to thereby perform light emission and that is formed in an arbitrary shape, and a base portion that includes a second end surface which supports the display portion and a third end surface on which the solar cell is arranged.

### Advantageous Effects of Invention

According to an aspect of the invention, an effect is achieved that a fluorescent concentrator solar cell is provided by which a high visual effect which has not achieved before is obtained by using a fluorescent concentrating plate while suppressing variation in electric current values among solar cells.

### BRIEF DESCRIPTION OF DRAWINGS

FIG. 1 is a perspective view illustrating a fluorescent concentrator solar cell according to Embodiment 1 of the invention.

FIG. 2 is a front view illustrating the fluorescent concentrator solar cell illustrated in FIG. 1.

FIG. 3 is a reference view for explaining a light guiding action in a case where a base portion is not provided in a fluorescent concentrating plate.

FIG. 4 is a front view for explaining a relation between a height of a display portion and a height of the base portion which are illustrated in FIG. 2.

FIGS. 5(a) to (g) are graphs illustrating light quantity distribution of light received by a solar cell array in a case where a ratio between the height of the display portion and the height of the base portion is changed.

FIG. 6 is a graph illustrating a variation coefficient of light receiving quantity and an output value of the solar cell array in the case where the ratio between the height of the display portion and the height of the base portion is changed.

FIG. 7 is a front view illustrating a fluorescent concentrator solar cell according to Embodiment 2 of the invention.

FIG. 8 is a front view for explaining a light guiding action of the fluorescent concentrator solar cell illustrated in FIG. 7.

FIG. 9(a) is a graph illustrating light quantity distribution of light propagated from a display portion to an upper end surface of a base portion, (b) is a graph illustrating light quantity distribution of light guided from the upper end surface to a lower end surface and side end surfaces by the base portion, and (c) is a graph illustrating light quantity distribution of light received by a solar cell array.

FIG. 10 is a front view illustrating a fluorescent concentrator solar cell according to Embodiment 3 of the invention.

FIG. 11 is a top view illustrating a peripheral end surface of a display portion illustrated in FIG. 10.

FIG. 12(a) is a top view illustrating a light emitting state of the peripheral end surface which is inclined with respect to a thickness direction of a fluorescent concentrating plate, and (b) is a top view illustrating a light emitting state of the peripheral end surface which is parallel to the thickness direction of the fluorescent concentrating plate.

FIG. 13 is a top view illustrating a modified example of the peripheral end surface of the display portion illustrated in FIG. 12(b).

FIG. 14 is a front view illustrating a fluorescent concentrator solar cell according to Embodiment 4 of the invention.

FIG. 15 is a front view illustrating a fluorescent concentrator solar cell according to Embodiment 5 of the invention.

FIG. 16 is a front view illustrating a modified example of a base portion illustrated in FIG. 15.

FIG. 17 is a front view illustrating a fluorescent concentrator solar cell according to Embodiment 6 of the invention.

FIG. 18(a) is a graph illustrating light quantity distribution of light propagated from a display portion to an upper end surface of a base portion, (b) is a graph illustrating light quantity distribution of light guided from a front surface and a rear surface to a lower end surface and a side end surface by the base portion, and (c) is a graph illustrating light quantity distribution of light received by a solar cell array.

FIG. 19 is a front view illustrating a fluorescent concentrator solar cell according to Embodiment 7 of the invention.

FIG. 20 is a side view illustrating a reflecting action of a rear surface reflecting layer illustrated in FIG. 19.

FIGS. 21(a) and (b) are front views each illustrating a modified example of the fluorescent concentrator solar cell illustrated in FIG. 19.

FIG. 22 is a front view illustrating a fluorescent concentrator solar cell according to Embodiment 8 of the invention.

FIGS. 23(a) and (b) are front views each illustrating a modified example of the fluorescent concentrator solar cell illustrated in FIG. 22.

FIG. 24 is a view illustrating a schematic configuration of a general fluorescent concentrator solar cell.

### DESCRIPTION OF EMBODIMENTS

### Embodiment 1

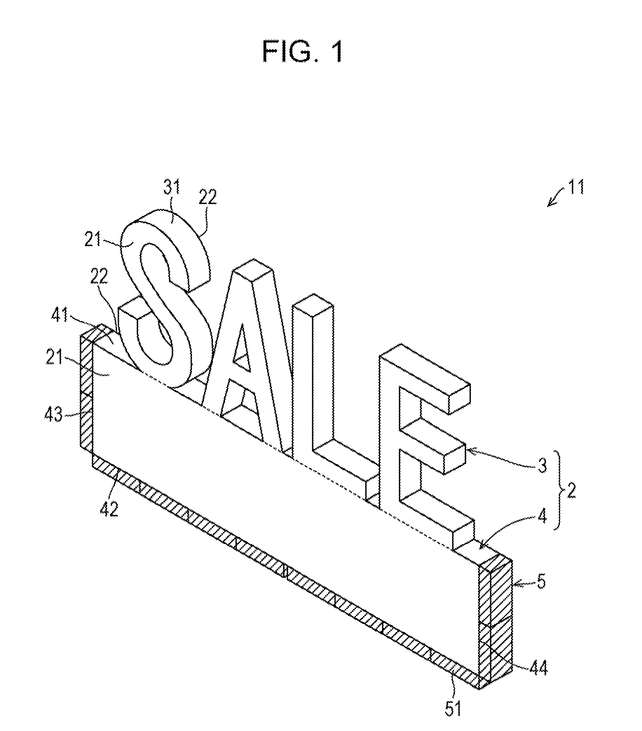

Hereinafter, an embodiment of the invention will be described as follows on the basis of FIG. 1 to FIG. 6.

### (Outline of Fluorescent Concentrator Solar Cell)

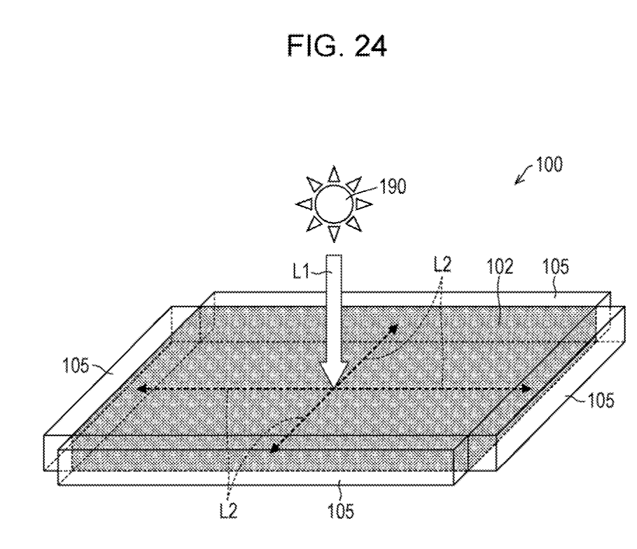

First, an outline of a general fluorescent concentrator solar cell will be simply described. FIG. 24 is a perspective view illustrating a schematic configuration of the fluorescent concentrator solar cell. Hereinafter, the fluorescent concentrator solar cell illustrated in FIG. 24 is referred to as a fluorescent concentrator solar cell 100.

The fluorescent concentrator solar cell 100 includes a fluorescent concentrating plate 102 and solar cell arrays 105. The fluorescent concentrator solar cell 100 is arranged so as to receive incident light L1 from a light source 190.

FIG. 24 illustrates an example of a case where the fluorescent concentrator solar cell 100 is arranged outdoors. Accordingly, the light source 190 is the sun, and the incident light L1 is sunlight. However, the fluorescent concentrator solar cell 100 may be arranged indoors. Thus, the light source is not limited only to the sun and may be, for example, an illumination device provided indoors.

The fluorescent concentrating plate 102 includes a phosphor excited by the incident light L1. The phosphor absorbs the incident light L1 serving as excitation light, and emits fluorescent light L2 having a wavelength longer than that of the incident light L1. Thus, the fluorescent concentrating plate 102 functions as a wavelength conversion member that receives the incident light L1 and emits the fluorescent light L2. Note that, a known material may be appropriately used for the phosphor in accordance with specifications of the fluorescent concentrator solar cell 100.

As illustrated in FIG. 24, the fluorescent concentrating plate 102 has four side surfaces each of which is in an oblong rectangle. On each of the four side surfaces of the fluorescent concentrating plate 102, each of the solar cell arrays 105 is provided. Note that, the number of side surfaces of the fluorescent concentrating plate 102 may not always be limited to four.

The fluorescent concentrating plate 102 is configured to guide the fluorescent light L2 toward each of the solar cell arrays 105. For example, the fluorescent concentrating plate 102 may be manufactured as one that is obtained by dispersing phosphors in a transparent acrylic plate.

The solar cell array 105 is a photoelectric conversion element that converts energy of the fluorescent light L2 guided by the fluorescent concentrating plate 102 into electric energy. That is, the solar cell array 105 receives the fluorescent light L2 and generates power. The solar cell array 105 means a circuit in which a plurality of solar cell modules are connected in series or in parallel. The solar cell module means a circuit in which a plurality of solar cells are connected in series or in parallel.

The fluorescent concentrator solar cell 100 mainly has the following advantages (1) to (4).

(1) Instead of the solar cell array 105, the incident light L1 is able to be received by the fluorescent concentrating plate 102. It is therefore possible to reduce an area of the solar cell compared with a general solar cell panel (non-concentrator solar cell).

Moreover, an additional optical member such as a lens or a reflector is not provided except for the above-described fluorescent concentrating plate 102, so that it is possible to realize a solar cell which is thinner and lighter than a concentrator solar cell provide with such an additional optical member.

(2) It is possible to absorb the incident light L1 and supply the fluorescent light L2 to the solar cell array 105 by the fluorescent concentrating plate 102. This makes it possible to generate power by the solar cell array 105 even when the incident light L1 is not incident almost vertically on a light-receiving surface of the fluorescent concentrating plate 102. Therefore, it is possible to reduce dependency of power generation quantity on an incident angle of light incident on the light-receiving surface compared with the above-described concentrator solar cell provided with the additional optical member.

(3) It is possible to receive the incident light L1 on any surface of the fluorescent concentrating plate 102. For example, the incident light L1 is able to be received also on a surface opposite to the surface on which the incident light L1 is received. As above, it is possible to receive the incident light L1 on the various surfaces of the fluorescent concentrating plate 102 to generate power by the solar cell array 105 compared with the above-described concentrator solar cell provided with the additional optical member.

(4) It is therefore possible to improve a degree of freedom of a shape of the fluorescent concentrating plate 102. For example, the fluorescent concentrating plate 102 which has a globular shape is also able to be realized, and the fluorescent concentrating plate 102 which is curved is also able to be realized. Moreover, it is possible to apply processing such as punching to the solar cell. In any case, the solar cell array 105 only needs to be arranged so as to be able to receive the fluorescent light L2 guided by the fluorescent concentrating plate 102.

The invention focuses on the above-described advantages (1) to (4), and, by giving a higher visual effect to the fluorescent concentrator solar cell, provides the fluorescent concentrator solar cell that is applicable to Point of Purchase (POP) advertisement for advertising a product or the like.

### (Configuration of Fluorescent Concentrator Solar Cell 11)

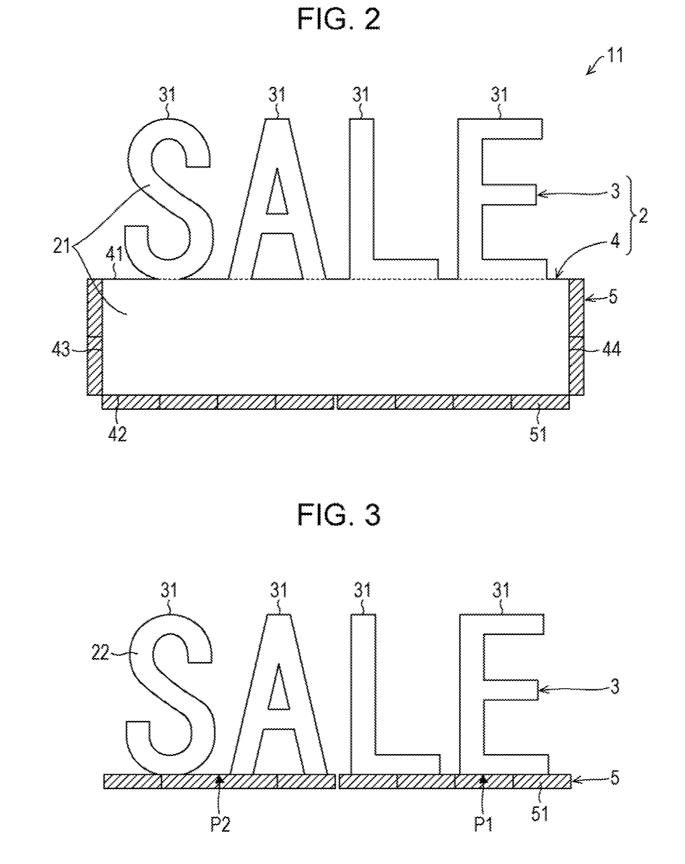

FIG. 1 is a perspective view illustrating a fluorescent concentrator solar cell 11 according to the present embodiment, and FIG. 2 is a front view illustrating the fluorescent concentrator solar cell 11 illustrated in FIG. 1. The fluorescent concentrator solar cell 11 is used as POP advertisement for advertising a product or the like, for example, in a commercial facility. Moreover, power generated by the fluorescent concentrator solar cell 11 is supplied to electronic equipment, such as a beacon oscillator, which is connected to the fluorescent concentrator solar cell 11, and used for driving electric equipment.

As illustrated in FIG. 1 and FIG. 2, the fluorescent concentrator solar cell 11 includes a fluorescent concentrating plate 2 and a solar cell array 5.

### (Fluorescent Concentrating Plate 2)

The fluorescent concentrating plate 2 is in a plate shape, and has a front surface 21 and a rear surface (facing surface) 22 each of which is the light-receiving surface that receives external light such as sunlight or illumination light, and a plurality of end surfaces (or side surfaces) each of which intersects with the front surface 21 and the rear surface 22. Light incident from the front surface 21 or the rear surface 22 of the fluorescent concentrating plate 2 is subjected to wavelength conversion into fluorescent light by a phosphor included in the fluorescent concentrating plate 2. A part of the light guided in an inside of the fluorescent concentrating plate 2 is emitted to an outside of the fluorescent concentrating plate 2, and the remaining part is concentrated to the solar cell array 5. The light concentrated to the solar cell array 5 is used for power generation by the solar cell array 5.

The fluorescent concentrating plate 2 converts the light incident on the fluorescent concentrating plate 2 into light in a wavelength region which is effective for photoelectric conversion in the solar cell array 5. Examples of the fluorescent concentrating plate 2 as above include one that is obtained by mixing a phosphor (fluorescent material) in a light guiding plate, one that is obtained by applying a phosphor to a light guiding plate, and the like.

A known phosphor is able to be used as the phosphor to be included in the fluorescent concentrating plate 2, and examples thereof include a hydrochloride or a sulfate of a rare earth metal such as coumarin fluorescent dye, samarium, terbium, europium, gadolinium, or dysprosium; transition metal acid salt such as calcium molybdate or calcium tungstate; aromatic hydrocarbon such as benzene or naphthalene; and phthalein dye such as eosin or fluorescein, but there is no limitation thereto.

Moreover, a known light guiding plate is able to be used as the light guiding plate, and examples thereof include an acrylic substrate, a glass substrate, and a polycarbonate substrate, but there is no limitation thereto.

A content of the phosphor in the fluorescent concentrating plate 2 is not particularly limited, but is preferably equal to or less than 1.0 wt %. Thereby, it is possible to realize efficient fluorescent light emittance in which multiple scattering caused by the phosphor is suppressed.

The fluorescent concentrating plate 2 includes a display portion 3 and a base portion 4 that is integrally connected to the display portion 3 and supports the display portion 3.

### (Display Portion 3)

The display portion 3 is configured by forming a part of the fluorescent concentrating plate 2 into an arbitrary shape such as a predetermined letter, figure, or symbol, and functions as POP advertisement. In the present embodiment, the fluorescent concentrating plate 2 includes, as the display portion 3, four letters which are formed into shapes of “S”, “A”, “L”, and “E”. A bottom part of each of the four letters of “S”, “A”, “L”, and “E” is integrally connected to the base portion 4.

A peripheral end surface (first end surface) 31 of the display portion 3 is processed so that a part of guided light is able to be emitted to the outside of the fluorescent concentrating plate 2. Thus, a part of light which is guided in an inside of the display portion 3 is emitted to the outside of the fluorescent concentrating plate 2 from the peripheral end surface 31 of the display portion 3. Moreover, light which is guided in the inside of the display portion 3 but is not emitted to the outside of the fluorescent concentrating plate 2 from the peripheral end surface 31 of the display portion 3 is propagated to an inside of the base portion 4.

Note that, the shape of the display portion 3 only needs to be formed so as to function as at least a part of POP advertisement, and is not necessarily formed so as to represent only a letter. For example, the display portion 3 may be formed so as to have a shape of an animation character, an animal, or the like.

### (Base Portion 4)

The base portion 4 functions as a base that supports each of the letters constituting the display portion 3. In the present embodiment, the base portion 4 is configured by forming a part of the fluorescent concentrating plate 2 into a rectangular shape which has long sides in an arrangement direction of the four letters constituting the display portion 3.

Specifically, the base portion 4 includes an upper end surface (second end surface) 41 that supports the display portion 3, a lower end surface (third end surface) 42 that is opposed to the upper end surface 41 approximately in parallel, and two side end surfaces (third end surfaces) 43 and 44 each of which is connected to each of the upper end surface 41 and the lower end surface 42 so as to form an angle of about 90°.

Note that, it is preferable that each of the angles formed by the lower end surface 42 and each of the side end surfaces 43 and 44 of the base portion 4 is not less than 90°. Focusing on solar cells 51, each of which is positioned at each ends, among solar cells 51 arranged on the lower end surface 42 of the base portion 4, in a case where each of the angles formed by the lower end surface 42 and each of the side end surfaces 43 and 44 is not less than 90°, a part of light received by a region of the base portion 4, which is surrounded by the upper end surface 41, the lower end surface 42, and the side end surfaces 43 and 44 (that is, the entire region of the base portion 4) is able to be concentrated to the solar cells 51 positioned at the both ends of the lower end surface 42.

On the other hand, in a case where each of the angles formed by the lower end surface 42 and each of the side end surfaces 43 and 44 is less than 90°, a part of light received by a smaller region of the base portion 4, which is surrounded by the lower end surface 42 and the side end surfaces 43 and 44, is mainly concentrated to the solar cells 51 positioned at the both ends of the lower end surface 42. Therefore, light quantity concentrated to the solar cells 51 positioned at the both ends of the lower end surface 42 is reduced compared with the case where each of the angles formed by the lower end surface 42 and each of the side end surfaces 43 and 44 is not less than 90°.

In light quantity distribution of light concentrated to the solar cells 51 arranged on the lower end surface 42 of the base portion 4, light quantity concentrated to the solar cells 51 positioned at the both ends of the lower end surface 42 normally becomes small. Thus, by setting each of the angles formed by the lower end surface 42 and each of the side end surfaces 43 and 44 to be not less than 90°, it is possible to achieve an effect that reduction in the light quantity concentrated to the solar cells 51 positioned at the both ends of the lower end surface 42 of the base portion 4 is able to be suppressed.

Accordingly, as described below, in a configuration in which distribution of light quantity propagated to the base portion 4 from the display portion 3 and light quantity distribution of light guided to the lower end surface 42 and the side end surfaces 43 and 44 by the base portion 4 complement each other, by setting each of the angles formed by the lower end surface 42 and each of the side end surfaces 43 and 44 of the base portion 4 to be not less than 90°, ununiformity of light receiving quantity among the solar cells 51 is improved more, so that it is possible to effectively equalize the light receiving quantity.

The upper end surface 41 is an end surface of the base portion 4, which is integrally connected to the display portion 3 to thereby support the display portion 3. Light which is not emitted to the outside of the fluorescent concentrating plate 2 from the peripheral end surface 31 of the display portion 3 is propagated to the inside of the base portion 4 from a connecting part (that is, a part indicated with a broken line in the figure) of the upper end surface 41, at which the display portion 3 is connected.

The lower end surface 42 and the side end surfaces 43 and 44 are end surfaces of the base portion 4 that concentrate the light propagated through the fluorescent concentrating plate 2 to the solar cell array 5. The solar cell array 5 is arranged on the lower end surface 42 and the side end surfaces 43 and 44.

The light propagated to the base portion 4 from the display portion 3 is guided in the inside of the base portion 4, concentrated to the solar cell array 5 arranged on the lower end surface 42 and the side end surfaces 43 and 44, and used for power generation.

Moreover, light incident from the front surface 21 and the rear surface 22 of the base portion 4 is subjected to wavelength conversion by the phosphor. Thereafter, the light is guided in the inside of the base portion 4, concentrated to the solar cell array 5 arranged on the lower end surface 42 and the side end surfaces 43 and 44, and used for power generation. Note that, details of the fluorescent concentrating plate 2 will be described below.

### (Solar Cell Array 5)

The solar cell array 5 converts light concentrated by the fluorescent concentrating plate 2 into electric power. In the solar cell array 5, solar cell modules each of which includes a plurality of solar cells 51 are connected in series or in parallel. A known solar cell is able to be used for the solar cell array 5, and examples thereof include an amorphous silicon (a-Si) solar cell, a polycrystalline silicon solar cell, a single crystal silicon solar cell, and a compound solar cell, but there is no limitation thereto.

The solar cell array 5 is attached to the lower end surface 42 and the side end surfaces 43 and 44 of the base portion 4 with the use of a known transparent adhesive or the like.

A size of the solar cell array 5 is not particularly limited, but it is preferable that a width of a light-receiving part of each of the solar cells 51 is the same as a thickness of each of the lower end surface 42 and the side end surfaces 43 and 44 of the base portion 4. It is thereby possible to efficiently receive light reaching the lower end surface 42 and the side end surfaces 43 and 44 of the base portion 4 by the solar cells 51.

The electric power generated by the solar cell array 5 is supplied to electric equipment, such as a beacon oscillator, which is connected to the solar cell array 5, and used for driving the electric equipment.

### (Details of Fluorescent Concentrating Plate 2)

As described above, the peripheral end surface 31 of the display portion 3 is processed so that a part of light guided in the display portion 3 is able to be emitted to the outside of the fluorescent concentrating plate 2. Specifically, the peripheral end surface 31 of the display portion 3 is a rough surface which has not been optically polished.

Therefore, a part of the light guided in the display portion 3 is emitted to the outside of the fluorescent concentrating plate 2 from the peripheral end surface 31 of the display portion 3, and thereby the peripheral end surface 31 of the display portion 3 emits light. Accordingly, when the display portion 3 is observed from a side of the front surface 21 of the display portion 3, a contour part of each of the letters of “SALE” emits light and is observed, so that, by using the fluorescent concentrating plate 2, it is possible to obtain a high visual effect which has not achieved before.

Moreover, light which is guided in the inside of the display portion 3 but is not emitted to the outside of the fluorescent concentrating plate 2 from the peripheral end surface 31 of the display portion 3 is propagated to the base portion 4 and concentrated to the solar cell array 5 which is arranged on the lower end surface 42 and the side end surfaces 43 and 44. At this time, the light propagated from the display portion 3 is dispersed during a light guiding process from the upper end surface 41 of the base portion 4 to the lower end surface 42 and the side end surfaces 43 and 44, so that ununiformity of light receiving quantity among the solar cells 51 is improved. Thus, it is possible to suppress occurrence of variation in electric current values generated by the solar cells 51.

FIG. 3 is a reference view for explaining a light guiding action in a case where the base portion 4 is not provided in the fluorescent concentrating plate 2. As illustrated in FIG. 3, in the case where the base portion 4 is not provided in the fluorescent concentrating plate 2, that is, in a case where the fluorescent concentrating plate 2 is configured by the display portion 3 constituted by “S”, “A”, “L”, and “E” and the solar cell array 5 is directly arranged on a bottom part of each of the letters, the solar cell array 5 includes a part to which light is concentrated by the display portion 3 and a part to which light is not concentrated.

That is, in the solar cell array 5, light is concentrated to the solar cell 51 at a position P1 which is in contact with (opposed to) the bottom part of the letter, but light is not concentrated to the solar cell 51 at a position P2 which is not in contact with the bottom part of the letter (for example, a gap between the letters). Therefore, light receiving quantity becomes ununiform among the solar cells 51, and variation in electric current values generated by the solar cells 51 is caused.

Then, in the fluorescent concentrator solar cell 11, by providing the base portion 4 between the display portion 3 and the solar cell array 5, ununiformity of light receiving quantity among the solar cells 51 is improved, and occurrence of variation in electric current values generated by the solar cells 51 is suppressed.

Light propagated to the base portion 4 from the letters constituting the display portion 3 is guided in the base portion 4 while being dispersed during the light guiding process to reach the lower end surface 42 and the side end surfaces 43 and 44 from the upper end surface 41 of the base portion 4. Therefore, the light propagated to the base portion 4 from the letters constituting the display portion 3 is distributed to the plurality of solar cells 51 to be concentrated, so that ununiformity of light receiving quantity among the solar cells 51 is improved. Thus, by providing the base portion 4 between the display portion 3 and the solar cell array 5, it is possible to suppress occurrence of variation in electric current values generated by the solar cells 51.

In addition, since light is incident also from the front surface 21 and the rear surface 22 of the base portion 4, it is possible to increase light absorbing quantity of the entire fluorescent concentrating plate 2. Thus, by providing the base portion 4, it is possible to increase power generation quantity of the fluorescent concentrator solar cell 11.

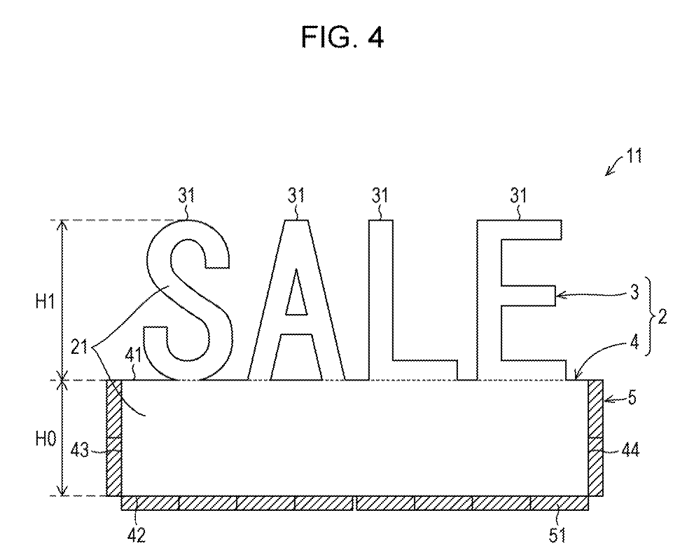

FIG. 4 is a front view for explaining a relation between a height H1 (width of the display portion 3 in a perpendicular direction of the upper end surface 41 as the second end surface) of the display portion 3 and a height H0 of the base portion 4.

A total surface area of the peripheral end surface 31 of the display portion 3 may be relatively large compared with a total surface area of the lower end surface 42 and the side end surfaces 43 and 44 of the base portion 4 on which the solar cell array 5 is arranged. Thereby, it is possible to reduce a difference between a maximum value and a minimum value of light quantity received by the solar cell array 5, thus making it possible to improve ununiformity of light receiving quantity among the solar cells 51.

Particularly, as illustrated in FIG. 4, when the height (width) of the display portion 3 in the perpendicular direction of the upper end surface 41 of the base portion 4 and the height of the base portion 4 in the perpendicular direction (that is, a distance between the upper end surface 41 and the lower end surface 42 of the base portion 4) are defined as H1 and H0, respectively, it is preferable that a mathematical relation of 1≤H1/H0≤4 is satisfied.

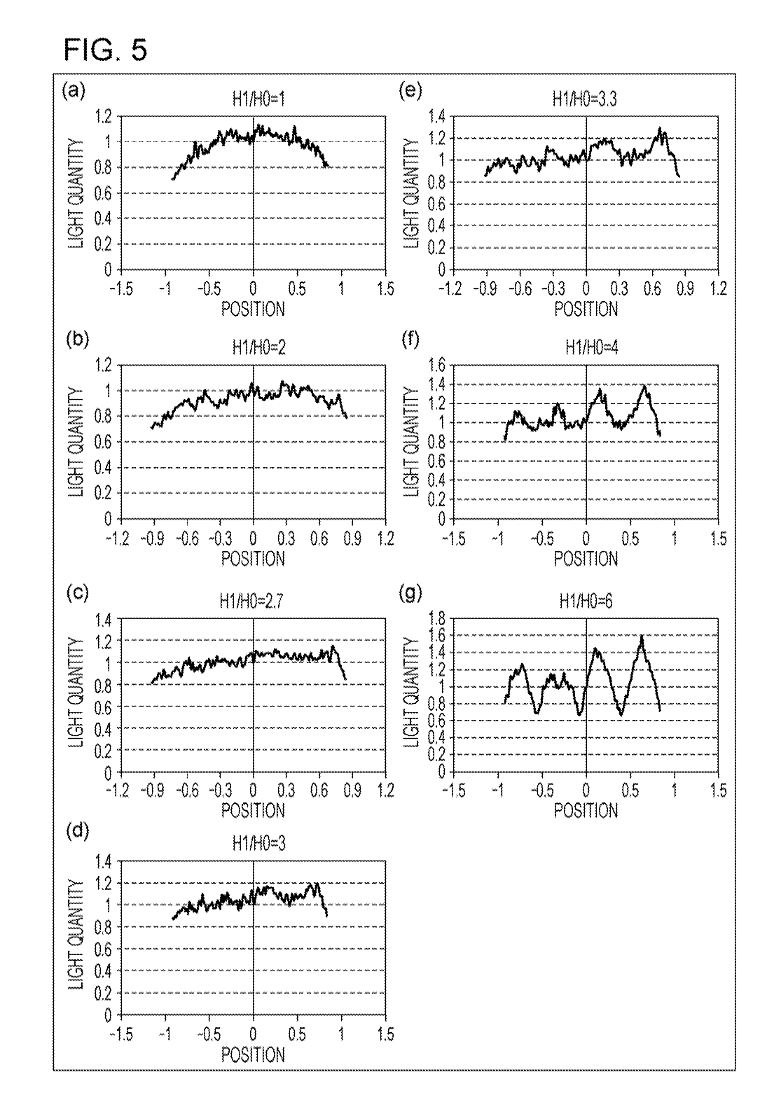

FIGS. 5(a) to (g) are graphs each illustrating light quantity distribution of light received by the solar cell array 5 in a case where a value of H1/H0 is changed. In FIGS. 5(a) to (g), a vertical axis indicates normalized light quantity received by the solar cell array 5, and a horizontal axis indicates positions of the solar cells 51. Specifically, on the horizontal axis, among the lower end surface 42 and the side end surfaces 43 and 44 of the base portion 4 on which the solar cell array 5 is arranged, a center position of the lower end surface 42 is indicated with “0”.

Moreover, FIGS. 5(a), (b), (c), (d), (e), (f), and (g) each illustrate light quantity distribution of light received by the solar cell array 5 in a case of H1/H0=1, in a case of H1/H0=2, in a case of H1/H0=2.7, in a case of H1/H0=3, in a case of H1/H0=3.3, in a case of H1/H0=4, and in a case of H1/H0=6, respectively.

As illustrated in FIGS. 5(a) to (g), the light quantity distribution of light received by the solar cell array 5 varies in accordance with the change in the value of H1/H0. Thus, by optimizing the value of H1/H0, it is possible to reduce variation in light receiving quantity among the solar cells 51.

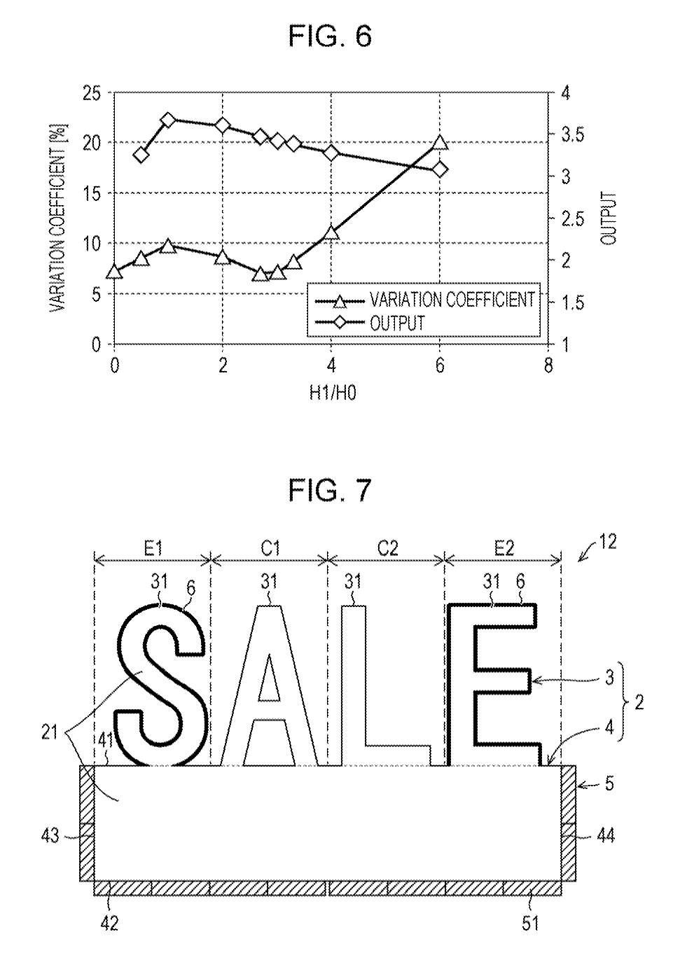

FIG. 6 is a graph illustrating a variation coefficient of light receiving quantity and an output value of the solar cell array 5 with each value of H1/H0. The variation coefficient indicated in FIG. 6 represents a change rate of a minimum value and a maximum value of light quantity received by the solar cell array 5 with each value of H1/H0.

As illustrated in FIG. 6, in a case of 1≤H1/H0≤4.0, it is possible to suppress the variation coefficient to about 10%. In a case of H1/H0=3, it is possible to suppress the variation coefficient to the lowest.

On the contrary, in a case of H1/H0<1, the output value of the solar cell array 5 is greatly lowered. Moreover, in a case of H1/H0>4, the variation coefficient exceeds 10%, and variation in light receiving quantity among the solar cells 51 is increased. Therefore, a power loss in the solar cell array 5 is increased.

Accordingly, by setting a ratio of the height H1 of the display portion 3 and the height H0 of the base portion 4 so that the mathematical relation of 1≤H1/H0≤4 is satisfied, preferably, H1/H0=3 is satisfied, it is possible to suppress variation in electric current values among the solar cells 51. This makes it possible to suitably reduce a power loss in the solar cell array 5.

### (Effect of Fluorescent Concentrator Solar Cell 11)

As described above, the fluorescent concentrator solar cell 11 according to the present embodiment is provided with the fluorescent concentrating plate 2 that includes a phosphor converting a wavelength of received light and guides the light, and the solar cell array 5 that includes the plurality of solar cells 51 each of which receives the light guided by the fluorescent concentrating plate 2.

The fluorescent concentrating plate 2 includes the display portion 3 that includes the peripheral end surface 31 which emits a part of the guided light to the outside to thereby perform light emission and that is formed in an arbitrary shape, and the base portion 4 that includes the upper end surface 41 which supports the display portion 3 and the lower end surface 42 and the side end surfaces 43 and 44 on which the solar cell array 5 is arranged.

In the aforementioned configuration, the display portion 3 formed in the arbitrary shape (of a letter, a figure, a symbol, or the like, for example) is designed so as to emit a part of the guided light to the outside of the fluorescent concentrating plate 2 from the peripheral end surface 31 to thereby perform light emission. It is therefore possible to emit light from a contour part of the display portion 3 formed in the arbitrary shape, thus making it possible to obtain a high visual effect, which has not achieved before, by using the fluorescent concentrating plate 2.

With the aforementioned configuration, since the fluorescent concentrating plate 2 itself functions as the display portion 3 formed in the arbitrary shape such as a letter, a figure, or a symbol and receiving and guiding light, it is possible to restrict the display portion 3 to shut out light. Furthermore, light which is guided in the display portion 3 but is not emitted to the outside of the fluorescent concentrating plate 2 from the peripheral end surface 31 of the display portion 3 is propagated to the base portion 4 from the upper end surface 41 of the base portion 4, guided in the inside of the base portion 4, and concentrated to the solar cell which are arranged on the lower end surface 42 and the side end surfaces 43 and 44. At this time, the light propagated to the base portion 4 from the display portion 3 is scattered during the light guiding process to reach the lower end surface 42 and the side end surfaces 43 and 44 from the upper end surface 41 of the base portion 4, so that ununiformity of light receiving quantity among the solar cells 51 is improved and equalized. Thus, it is possible to suppress occurrence of variation in electric current values generated by the solar cells 51.

Accordingly, with the aforementioned configuration, it is possible to realize the fluorescent concentrator solar cell 11 by which a high visual effect which has not achieved before is obtained by using the fluorescent concentrating plate 2 while suppressing variation in electric current values among the solar cells 51.

### Embodiment 2

Another embodiment of the invention will be described as follows on the basis of FIG. 7 to FIG. 9. Note that, for convenience of description, the same reference signs are assigned to members having the same functions as those of the members described in the aforementioned embodiment, and description thereof is omitted.

### (Configuration of Fluorescent Concentrator Solar Cell 12)

A fluorescent concentrator solar cell 12 according to the present embodiment is different from the fluorescent concentrator solar cell 11 according to Embodiment 1 in that a reflecting layer 6 is provided in a part of the display portion 3 of the fluorescent concentrating plate 2.

FIG. 7 is a front view illustrating the fluorescent concentrator solar cell 12 according to the present embodiment. As illustrated in FIG. 7, the fluorescent concentrator solar cell 12 includes the fluorescent concentrating plate 2, the solar cell array 5, and the reflecting layer (first reflecting member) 6.

### (Reflecting Layer 6)

The reflecting layer 6 is a reflecting member that reflects light emitted from the peripheral end surface 31 of the display portion 3 to the peripheral end surface 31. In the display portion 3 constituted by the four letters of “S”, “A”, “L”, and “E”, the reflecting layer 6 is provided in parts of the peripheral end surface 31 of the display portion 3, which correspond to “S” and “E” that are positioned at both ends, in the present embodiment.

Specifically, in a case where the base portion 4 is divided into four (approximately equally divided into four) in a longitudinal direction in accordance with the number of letters included in the display portion 3 (four, in the present invention), when a region on a side end surface 43 side is defined as an end part E1, a region on a side end surface 44 side is defined as an end part E2, and regions between the end part E1 and the end part E2 are defined as center parts C1 and C2, the reflecting layer 6 is provided in the part of the peripheral end surface 31, which corresponds to “S” connected to the end part E1 of the base portion 4, and the part of the peripheral end surface 31, which corresponds to “E” connected to the end part E2 of the base portion 4. On the other hand, the reflecting layer 6 is not provided in a part of the peripheral end surface 31, which corresponds to “A” connected to the center part C1 of the base portion 4, or a part of the peripheral end surface 31, which corresponds to “L” connected to the center part C2 of the base portion 4.

In this manner, by providing the reflecting layer 6 only in the parts of the peripheral end surface 31 of the display portion 3, which correspond to “S” and “E”, it is possible to restrict light to be emitted to the outside of the fluorescent concentrating plate 2 from parts of the display portion 3, which correspond to “S” and “E”. Thereby, it is possible to make light quantity propagated to the both end parts E1 and E2 of the base portion 4 from the parts of the display portion 3, which correspond to “S” and “E”, relatively large compared with light quantity propagated to the center parts C1 and C2 of the base portion 4 from parts of the display portion 3, which correspond to “A” and “K”. Thus, it is possible to aim to equalize light receiving quantity of the solar cells 51 as described below.

Moreover, since light quantity propagated to the base portion 4 from the display portion 3 is increased, light quantity used for power generation by the solar cell array 5 is also increased. Therefore, it is possible to increase power generation quantity which is able to be taken out from the entire fluorescent concentrator solar cell 12.

Examples of the reflecting layer 6 include a metal thin film (aluminum, silver, titanium, chromium, or the like) and reflective ink (reflective paint or the like). In a case where, as the reflecting layer 6, a metal reflecting layer is partially provided in the peripheral end surface 31 of the display portion 3, external light reflection is subjected to metallic reflection to the peripheral end surface 31 of the display portion 3 and observed when being observed from an outside. Thus, it is possible to improve design of the display portion 3.

Moreover, the reflecting layer 6 may be a derivative multilayer film (a laminated film, a laminated deposition film, or the like) that selectively reflects light in a predetermined wavelength region. In a case where, as the reflecting layer 6, a derivative multilayer film is provided in the peripheral end surface 31 of the display portion 3, it is possible to cause the peripheral end surface 31 of the display portion 3 to emit light of any color when being observed from the outside. Thus, it is possible to improve design of the display portion 3.

Moreover, by providing, as the reflecting layer 6, a derivative multilayer film which selectively reflects, for example, red light in the peripheral end surface 31 of the display portion 3, it is possible to selectively reflect red light guided in the inside of the display portion 3 and propagate it to the base portion 4 to use it for power generation by the solar cell array 5.

### (Effect of Fluorescent Concentrator Solar Cell 12)

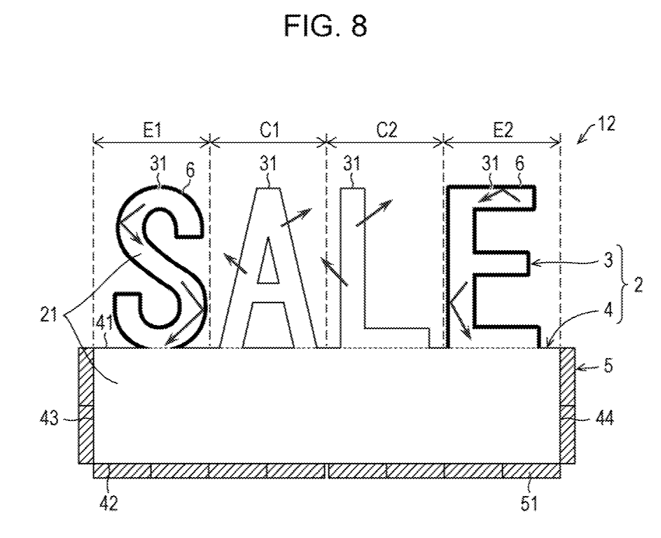

FIG. 8 is a front view for explaining a light guiding action of the fluorescent concentrator solar cell 12 according to the present embodiment. As illustrated in FIG. 8, by providing the reflecting layer 6 in the parts of the peripheral end surface 31 of the display portion 3, which correspond to “S” and “E” connected to the both end parts E1 and E2 of the base portion 4, light emission from the parts of the peripheral end surface 31 of the display portion 3, which correspond to “S” and “E”, is suppressed. Accordingly, light quantity propagated to the both end parts E1 and E2 of the base portion 4 from the parts of the display portion 3, which correspond to “S” and “E”, becomes relatively large compared with light quantity propagated to the center parts C1 and C2 of the base portion 4 from the parts of the display portion 3, which correspond to “A” and “L”.

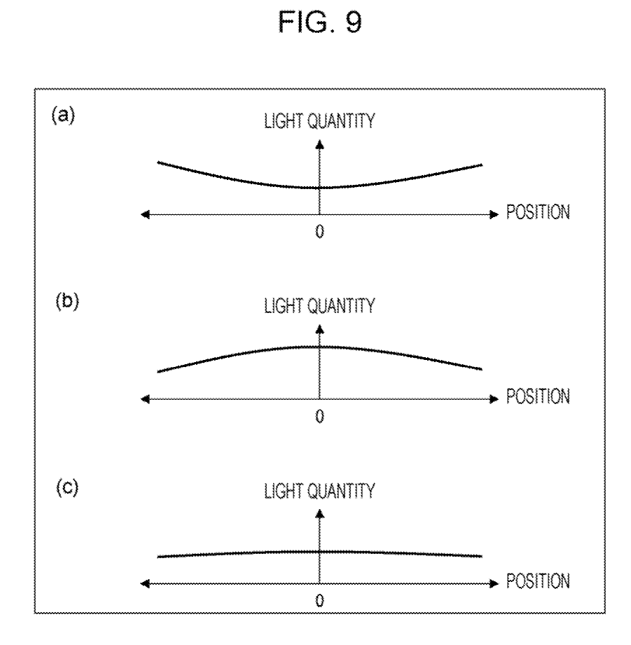

FIG. 9(a) is a graph illustrating light quantity distribution of light propagated from the display portion 3 to the upper end surface 41 of the base portion 4, FIG. 9(b) is a graph illustrating light quantity distribution of light guided from the upper end surface 41 to the lower end surface 42 and side end surfaces 43 and 44 by the base portion 4, and FIG. 9(c) is a graph illustrating light quantity distribution of light received by the solar cell array 5.

As illustrated in FIG. 9(b), in a case where light is incident from the upper end surface 41 of the base portion 4, there is a tendency that, in the base portion 4 having a rectangular shape, light concentrating efficiency (light guiding quantity) to the center position of the lower end surface 42 of the base portion 4 is high and the light concentrating efficiency becomes lower as moving away from the center position of the lower end surface 42. That is, there is a tendency that light receiving quantity of the solar cell 51 arranged at the center position of the lower end surface 42 of the base portion 4 is large, and light receiving quantity of each of the solar cells 51 arranged on the side end surfaces 43 and 44 which are positioned away from the center position of the lower end surface 42 is small.

Accordingly, in a case where light having uniform light quantity is incident from the upper end surface 41 of the base portion 4, light receiving quantity becomes ununiform among the solar cells 51, and variation in electric current values generated by the solar cells 51 is caused.

Then, by providing the reflecting layer 6 in the parts of the peripheral end surface 31 of the display portion 3, which correspond to “S” and “E” connected to the both end parts E1 and E2 of the base portion 4, ununiformity of light receiving quantity among the solar cells 51 is improved in the fluorescent concentrator solar cell 12.

That is, as illustrated in FIG. 9(a), by providing the reflecting layer 6 in the parts of the peripheral end surface 31 of the display portion 3, which correspond to “S” and “E” connected to the both end parts E1 and E2 of the base portion 4, it is possible to make light quantity propagated to the both end parts E1 and E2 of the base portion 4 from the parts of the display portion 3, which correspond to “S” and “E”, relatively large compared with light quantity propagated to the center parts C1 and C2 of the base portion 4 from the parts of the display portion 3, which correspond to “A” and “L”.

Thereby, since the distribution of the light quantity propagated to the upper end surface 41 of the base portion 4 from the display portion 3, which is illustrated in FIG. 9(a), and the light quantity distribution of the light guided to the lower end surface 42 and the side end surfaces 43 and 44 from the upper end surface 41 by the base portion 4 having the rectangular shape, which is illustrated in FIG. 9(b), complement each other, ununiformity of light receiving quantity among the solar cells 51 is improved as illustrated in FIG. 9(c), so that it is possible to equalize the light receiving quantity.

Note that, the reflecting layer 6 may be partially provided in the parts of the peripheral end surface 31, which correspond to “S” and “E”. Thereby, it is possible to equalize light receiving quantity among the solar cells 51 while causing a contour part of each of the letters of “S” and “E” to partially emit light.

### Embodiment 3

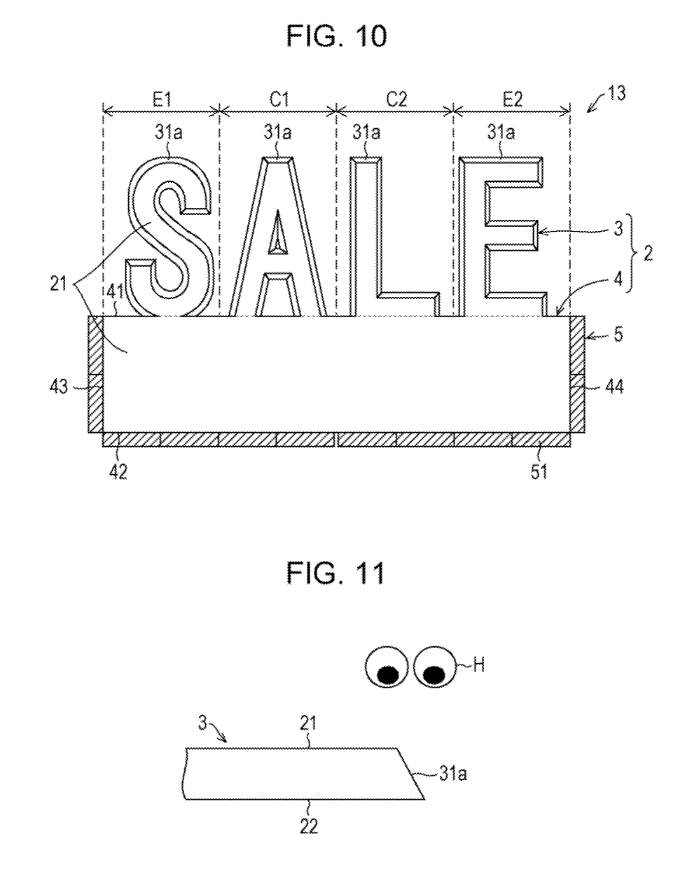

Another embodiment of the invention will be described as follows on the basis of FIG. 10 to FIG. 13. Note that, for convenience of description, the same reference signs are assigned to members having the same functions as those of the members described in the aforementioned embodiments, and description thereof is omitted.

### (Configuration of Fluorescent Concentrator Solar Cell 13)

A fluorescent concentrator solar cell 13 according to the present embodiment is different from the fluorescent concentrator solar cell 11 according to Embodiment 1 in that a peripheral end surface 31a of the display portion 3 of the fluorescent concentrating plate 2 is inclined with respect to a thickness direction of the fluorescent concentrating plate 2.

FIG. 10 is a front view illustrating the fluorescent concentrator solar cell 13 according to the present embodiment. As illustrated in FIG. 10, the fluorescent concentrator solar cell 13 includes the fluorescent concentrating plate 2 and the solar cell array 5. The fluorescent concentrating plate 2 of the fluorescent concentrator solar cell 13 has the display portion 3 that includes the peripheral end surface 31a which is inclined with respect to the thickness direction of the fluorescent concentrating plate 2.

### (Peripheral End Surface 31a)

FIG. 11 is a top view illustrating the peripheral end surface 31a of the display portion 3. As illustrated in FIG. 11, the peripheral end surface 31a of the display portion 3 is cut so as to be inclined with respect to the thickness direction of the fluorescent concentrating plate 2. Specifically, the peripheral end surface 31a is inclined so that an area of a cross section of the fluorescent concentrating plate 2, which is taken along a plane substantially parallel to the front surface 21 of the fluorescent concentrating plate 2, becomes gradually large as coming closer to the rear surface 22 from the front surface 21.

### (Effect of Fluorescent Concentrator Solar Cell 13)

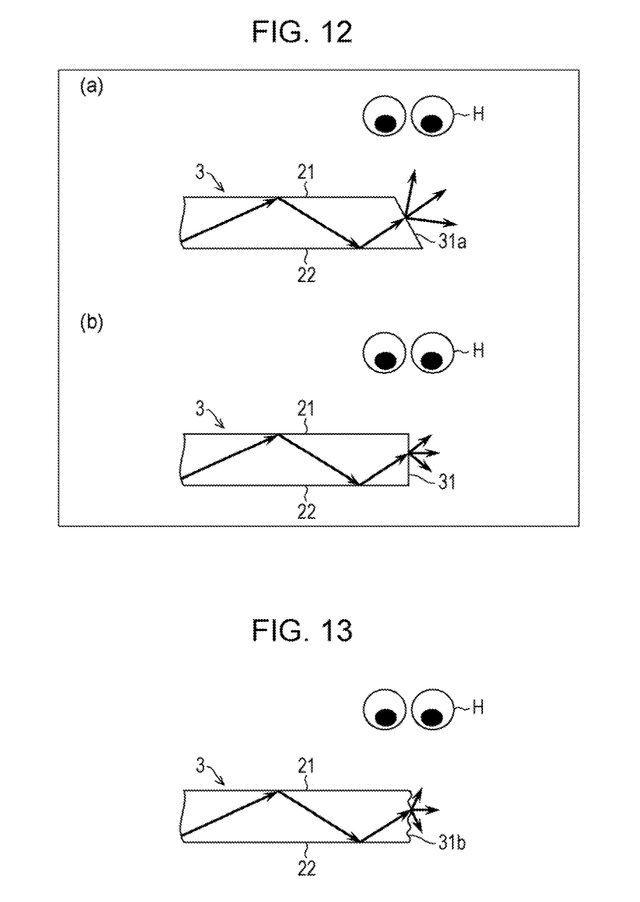

FIG. 12(a) is a top view illustrating a light emitting state of the peripheral end surface 31a which is inclined with respect to the thickness direction of the fluorescent concentrating plate 2, and FIG. 12(b) is a top view illustrating a light emitting state of the peripheral end surface 31 which is parallel to the thickness direction of the fluorescent concentrating plate 2.

As illustrated in FIGS. 12 (a) and (b), the peripheral end surface 31a which is inclined with respect to the thickness direction of the fluorescent concentrating plate 2 has a surface area which is relatively large compared with that of the peripheral end surface 31 parallel to the thickness direction of the fluorescent concentrating plate 2. Accordingly, more light is emitted to the outside of the fluorescent concentrating plate 2 from the peripheral end surface 31a. Moreover, since the peripheral end surface 31a is inclined to a side of an observer H who is positioned on a side of the front surface 21 of the fluorescent concentrating plate 2, light quantity emitted toward the observer H is increased.

Therefore, in a case where the observer H observes the display portion 3 from the front surface 21 of the fluorescent concentrating plate 2, the contour part of each of the letters “SALE” is observed by the observer H more remarkably, so that it is possible to enhance a visual effect of the display portion 3.

As above, in the fluorescent concentrator solar cell 13, the peripheral end surface 31a of the display portion 3 of the fluorescent concentrating plate 2 is inclined with respect to the thickness direction of the fluorescent concentrating plate 2, so that more light is emitted to the outside of the fluorescent concentrating plate 2 from the peripheral end surface 31a of the display portion 3.

Thus, according to the aforementioned configuration, the contour part of the display portion 3 is observed more remarkably, so that it is possible to enhance the visual effect of the display portion 3.

Note that, in the display portion 3 constituted by the four letters of “S”, “A”, “L”, and “E”, the inclined peripheral end surface 31a may be formed only in the parts of the display portion 3, which correspond to “A” and “L” connected to the center parts C1 and C2 of the base portion 4, for example. Thereby, light quantity propagated to the center parts C1 and C2 of the base portion 4 from the parts of the display portion 3, which correspond to “A” and “L” connected to the center parts C1 and C2. Thus, it is possible to make light quantity propagated to the center parts C1 and C2 of the base portion 4 from the parts of the display portion 3, which correspond to “A” and “L”, relatively small compared with light quantity propagated to the both end parts E1 and E2 of the base portion 4 from the parts of the display portion 3, which correspond to “S” and

Accordingly, since light quantity distribution (refer to FIG. 9(a)) of light propagated to the upper end surface 41 of the base portion 4 from the display portion 3 and light quantity distribution of light guided to the lower end surface 42 and the side end surfaces 43 and 44 from the upper end surface 41 by the base portion 4 having the rectangular shape complement each other, ununiformity of light receiving quantity among the solar cells 51 is improved, so that it is possible to equalize the light receiving quantity.

### Modified Example

FIG. 13 is a top view illustrating a modified example of the peripheral end surface 31 of the display portion 3 illustrated in FIG. 12(b). As illustrated in FIG. 13, minute roughness may be formed on a peripheral end surface 31b of the display portion 3 by roughening a surface thereof.

The peripheral end surface 31b on which the minute roughness is formed has a surface area that is relatively large compared with that of the peripheral end surface 31 which is flat. Accordingly, more light is emitted to the outside from the peripheral end surface 31b of the display portion 3. Moreover, when the minute roughness is formed, light is emitted from the peripheral end surface 31b in a wide angle range, so that it is possible to efficiently emit light toward the side of the observer H.

Thus, the contour part of the display portion 3 is observed more remarkably, so that it is possible to enhance a visual effect of the display portion 3.

### Embodiment 4

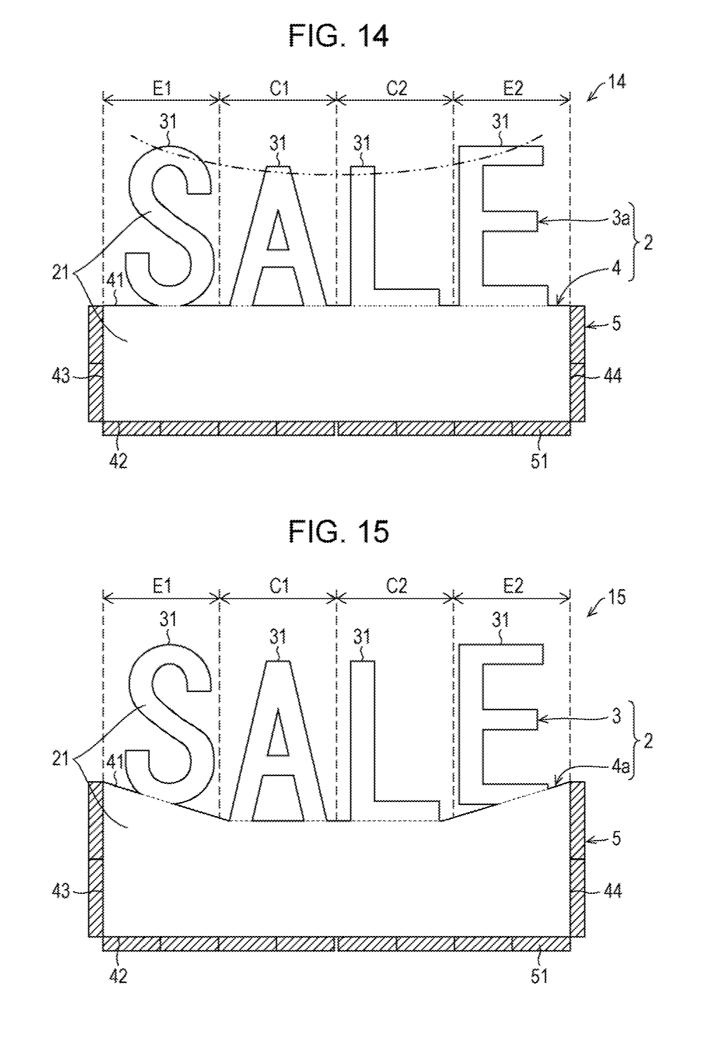

Another embodiment of the invention will be described as follows on the basis of FIG. 14. Note that, for convenience of description, the same reference signs are assigned to members having the same functions as those of the members described in the aforementioned embodiments, and description thereof is omitted.

### (Configuration of Fluorescent Concentrator Solar Cell 14)

A fluorescent concentrator solar cell 14 according to the present embodiment is different from the fluorescent concentrator solar cell 11 according to Embodiment 1 in that sizes of letters constituting a display portion 3a of the fluorescent concentrating plate 2 are changed.

FIG. 14 is a front view illustrating the fluorescent concentrator solar cell 14 according to the present embodiment. As illustrated in FIG. 14, the fluorescent concentrator solar cell 14 includes the fluorescent concentrating plate 2 and the solar cell array 5. The fluorescent concentrating plate 2 of the fluorescent concentrator solar cell 14 has the display portion 3a.

### (Display Portion 3a)

In the display portion 3a constituted by four letters of “S”, “A”, “L”, and “E”, the sizes of “S” and “E” connected to the both end parts E1 and E2 of the base portion 4 are relatively large compared with the sizes of “A” and “L” connected to the center parts C1 and C2 of the base portion 4. In other word, surface areas of parts of the front surface 21 and the rear surface 22 of the display portion 3a, which correspond to “S” and “E” connected to the both end parts E1 and E2 of the base portion 4, are relatively large compared with surface areas of parts of the front surface 21 and the rear surface 22 of the display portion 3a, which correspond to “A” and “L” connected to the center parts C1 and C2 of the base portion 4.

Accordingly, light receiving quantity of the parts of the display portion 3a, which correspond to “S” and “E” connected to the both end parts E1 and E2 of the base portion 4, is relatively large compared with light receiving quantity of the parts of the display portion 3a, which correspond to “A” and “L” connected to the center parts C1 and C2 of the base portion 4. Thus, light quantity propagated to the center parts C1 and C2 of the base portion 4 from the parts of the display portion 3a, which correspond to “S” and “E”, is relatively large compared with light quantity propagated to the both end parts E1 and E2 of the base portion 4 from the parts of the display portion 3a, which correspond to “S” and “E”.

### (Effect of the Fluorescent Concentrator Solar Cell 14)

As above, with the fluorescent concentrator solar cell 14, it is possible to make light quantity propagated to the both end parts E1 and E2 of the base portion 4 from the display portion 3a relatively large compared with light quantity propagated to the center parts C1 and C2 of the base portion 4 from the display portion 3a.

Accordingly, since light quantity distribution (refer to FIG. 9(a)) of light propagated to the upper end surface 41 of the base portion 4 from the display portion 3a and light quantity distribution (refer to FIG. 9(b)) of light guided to the lower end surface 42 and the side end surfaces 43 and 44 from the upper end surface 41 by the base portion 4 having the rectangular shape complement each other, ununiformity of light receiving quantity among the solar cells 51 is improved, so that it is possible to equalize the light receiving quantity.

### Embodiment 5

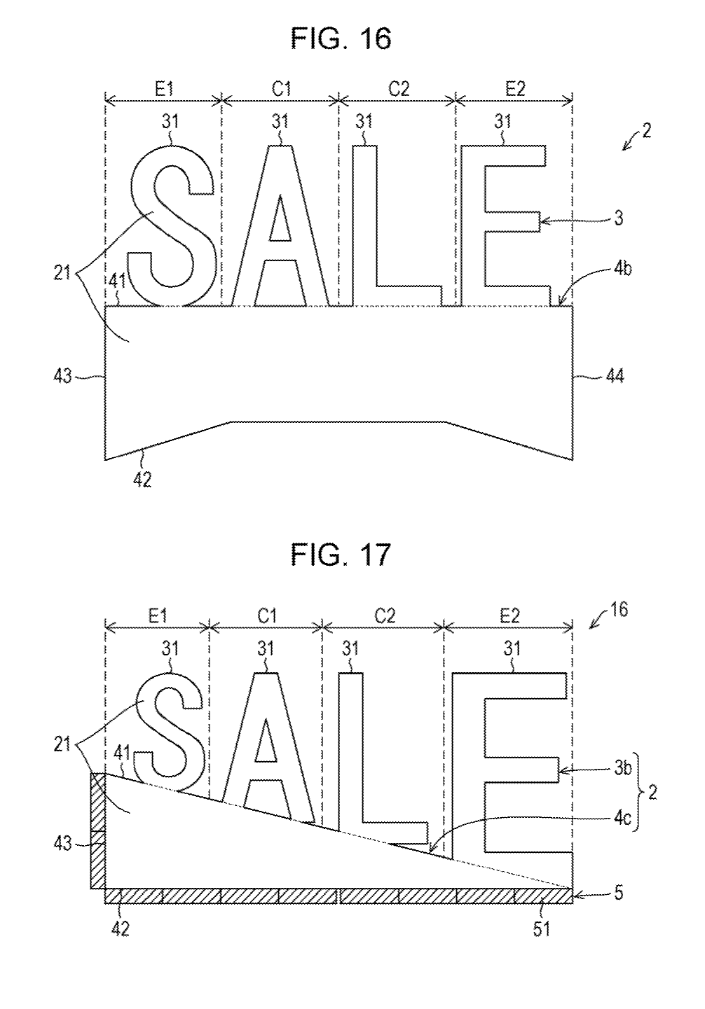

Another embodiment of the invention will be described as follows on the basis of FIG. 15 and FIG. 16. Note that, for convenience of description, the same reference signs are assigned to members having the same functions as those of the members described in the aforementioned embodiments, and description thereof is omitted.

### (Configuration of Fluorescent Concentrator Solar Cell 15)

A fluorescent concentrator solar cell 15 according to the present embodiment is different from the fluorescent concentrator solar cell 11 according to Embodiment 1 in that a height of a base portion 4a of the fluorescent concentrating plate 2 is changed.

FIG. 15 is a front view illustrating the fluorescent concentrator solar cell 15 according to the present embodiment. As illustrated in FIG. 15, the fluorescent concentrator solar cell 14 includes the fluorescent concentrating plate 2 and the solar cell array 5. The fluorescent concentrating plate 2 of the fluorescent concentrator solar cell 15 includes the base portion 4a.

### (Base Portion 4a)

In the base portion 4a, the height (width) of the base portion 4a in each of the both end parts E1 and E2 is relatively high compared with the height (width) of the base portion 4a in each of the center parts C1 and C2. In other words, in the base portion 4a, a distance between the upper end surface 41 and the lower end surface 42 in each of the both end parts E1 and E2 is relatively long compared with the distance between the upper end surface 41 and the lower end surface 42 in each of the center parts C1 and C2.

Specifically, the upper end surface 41 in the end part E1 of the base portion 4a is inclined so that the distance to the lower end surface 42 becomes longer as being closer to the side end surface 43. Moreover, the upper end surface 41 in the end part E2 of the base portion 4a is inclined so that the distance to the lower end surface 42 becomes longer as being closer to the side end surface 44. Thereby, surface areas of the front surface 21 and the rear surface 22 in the both end parts E1 and E2 of the base portion 4a are relatively large compared with surface areas of the front surface 21 and the rear surface 22 in the center parts C1 and C2 of the base portion 4.

Thus, among the both end parts E1 and E2 and the center parts C1 and C2 of the base portion 4a, light receiving quantity of the both end parts E1 and E2 of the base portion 4a is relatively large compared with light receiving quantity of the center parts C1 and C2 of the base portion 4a. It is therefore possible to concentrate more light to the solar cells 51 arranged on the both end parts E1 and E2 of the base portion 4a.

### (Effect of Fluorescent Concentrator Solar Cell 15)

As above, in the fluorescent concentrator solar cell 15, the light receiving quantity of the both end parts E1 and E2 of the base portion 4a is relatively large compared with the light receiving quantity of the center parts C1 and C2 of the base portion 4a, so that it is possible to concentrate relatively much light to the solar cells 51 arranged on the both end parts E1 and E2 of the base portion 4a.

Accordingly, since light quantity of the both end parts E1 and E2 in which the light quantity is lowered in the light quantity distribution (refer to FIG. 9(b)) of the light guided to the lower end surface 42 and side end surfaces 43 and 44 from the upper end surface 41 of the base portion 4 having the rectangular shape is able to be complemented in the base portion 4a, ununiformity of light receiving quantity among the solar cells 51 is improved, so that it is possible to equalize the light receiving quantity.

### Modified Example

FIG. 16 is a front view illustrating a modified example of the base portion 4a illustrated in FIG. 15. By inclining the lower end surface 42 in the both end parts E1 and E2 as a base portion 4b illustrated in FIG. 16, a height of each of the both end parts E1 and E2 of the base portion 4b may be made relatively high compared with a height of each of the center parts C1 and C2 of the base portion 4b.

Even with such a shape, light receiving quantity of the both end parts E1 and E2 of the base portion 4b is relatively large compared with light receiving quantity of the center parts C1 and C2 of the base portion 4b, so that it is possible to concentrate relatively much light to the solar cells 51 arranged on the both end parts E1 and E2 of the base portion 4b.

Accordingly, since light quantity of the both end parts E1 and E2 in which the light quantity is lowered in the light quantity distribution (refer to FIG. 9(b)) of the light guided to the lower end surface 42 and side end surfaces 43 and 44 from the upper end surface 41 of the base portion 4 having the rectangular shape is able to be complemented in the base portion 4b, ununiformity of light receiving quantity among the solar cells 51 is improved, so that it is possible to equalize the light receiving quantity.

### Embodiment 6

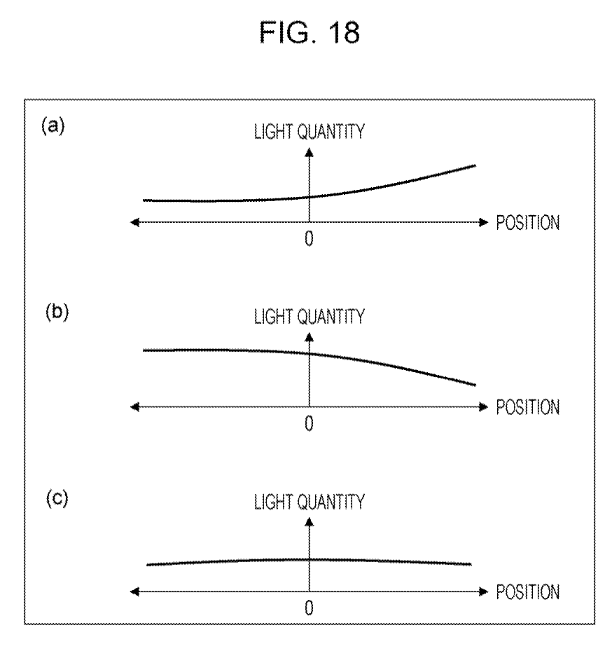

Another embodiment of the invention will be described as follows on the basis of FIG. 17 and FIG. 18. Note that, for convenience of description, the same reference signs are assigned to members having the same functions as those of the members described in the aforementioned embodiments, and description thereof is omitted.

### (Configuration of Fluorescent Concentrator Solar Cell 16)

A fluorescent concentrator solar cell 16 according to the present embodiment is different from the fluorescent concentrator solar cell 11 according to Embodiment 1 in that a size of a display portion 3b supported by a base portion 4c is changed in accordance with a height of the base portion 4c.

FIG. 17 is a front view illustrating the fluorescent concentrator solar cell 15 according to the present embodiment. As illustrated in FIG. 17, the fluorescent concentrator solar cell 16 includes the fluorescent concentrating plate 2 and the solar cell array 5. The fluorescent concentrating plate 2 of the fluorescent concentrator solar cell 15 has the display portion 3b and the base portion 4c.

### (Display Portion 3b)

In the display portion 3b constituted by four letters of “S”, “A”, “L”, and “E”, sizes thereof gradually become larger in an order of “S” connected to the end part E1 of the base portion 4c, “A” connected to the center part C1 of the base portion 4c, “L” connected to the center part C2 of the base portion 4c, and “E” connected to the end part E2 of the base portion 4c. In other words, surface areas of the front surface 21 and the rear surface 22 become relatively large in the order of “S”, “A”, “L”, and “E”.

Accordingly, light quantity propagated to the base portion 4 from the display portion 3b is increased in an order of light quantity propagated to the end part E1 of the base portion 4c from “S” in the display portion 3b, light quantity propagated to the center part C1 of the base portion 4c from “A” in the display portion 3b, light quantity propagated to the center part C2 of the base portion 4c from “L” in the display portion 3b, and light quantity propagated to the end part E2 of the base portion 4c from “E” in the display portion 3b.

### (Base Portion 4c)

The height (width) of the base portion 4c is reduced as, from the end part E1 (one end part) to which “S” in the display portion 3b is connected, coming closer to the end part E2 (the other end part) to which “E” in the display portion 3b is connected. In other words, the base portion 4c is in a right-angled triangle in which the upper end surface 41 is inclined so that the distance between the upper end surface 41 and the lower end surface 42 becomes gradually shorter as coming closer to the end part E1, the center part C1, the center part C2, and the end part E2.

Therefore, in the base portion 4c, surface areas of the front surface 21 and the rear surface 22 become relatively smaller in an order of the end part E1, the center part C1, the center part C2, and the end part E2. Accordingly, light receiving quantity of the base portion 4a is reduced in the order of the end part E1 to which “S” in the display portion 3b is connected, the center part C1 to which “A” in the display portion 3b is connected, the center part C2 to which “L” in the display portion 3b is connected, and the end part E2 to which “E” in the display portion 3b is connected.

Light propagated to the base portion 4c from the display portion 3b is guided in an inside of the base portion 4c, concentrated to the solar cell array 5 arranged on the lower end surface 42 and the side end surface 43, and used for power generation.

Light incident from the front surface 21 and the rear surface 22 of the base portion 4c is subjected to wavelength conversion by a phosphor. Thereafter, the light is guided in the inside of the base portion 4c, concentrated to the solar cell array 5 arranged on the lower end surface 42 and the side end surface 43, and used for power generation.

### (Effect of Fluorescent Concentrator Solar Cell 16)

FIG. 18(a) is a graph illustrating light quantity distribution of light propagated from the display portion 3b to the upper end surface 41 of the base portion 4c, FIG. 18(b) is a graph illustrating light quantity distribution of light guided from the front surface 21 and the rear surface 22 to the lower end surface 42 and the side end surface 43 by the base portion 4c, and FIG. 18(c) is a graph illustrating light quantity distribution of light received by the solar cell array 5.

As illustrated in FIG. 18(a), light quantity propagated to the upper end surface 41 of the base portion 4c from the display portion 3b is increased in the order of the light quantity propagated to the end part E1 of the base portion 4c from “S” in the display portion 3b, the light quantity propagated to the center part C1 of the base portion 4c from “A” in the display portion 3b, the light quantity propagated to the center part C2 of the base portion 4c from “L” in the display portion 3b, and the light quantity propagated to the end part E2 of the base portion 4c from “E” in the display portion 3b.

On the contrary, light receiving quantity received by the base portion 4a with the front surface 21 and the rear surface 22 is reduced in the order of the end part E1 to which “S” in the display portion 3b is connected, the center part C1 to which “A” in the display portion 3b is connected, the center part C2 to which “L” in the display portion 3b is connected, and the end part E2 to which “E” in the display portion 3b is connected.

Accordingly, since the light quantity distribution of the light propagated to the upper end surface 41 of the base portion 4c from the display portion 3b, which is illustrated in FIG. 18(a), and the light quantity distribution of the light guided to the lower end surface 42 and the side end surface 43 from the front surface 21 and the rear surface 22 by the base portion 4c, which is illustrated in FIG. 18(b), complement each other, ununiformity of light receiving quantity among the solar cells 51 is improved, so that it is possible to equalize the light receiving quantity.

### Embodiment 7

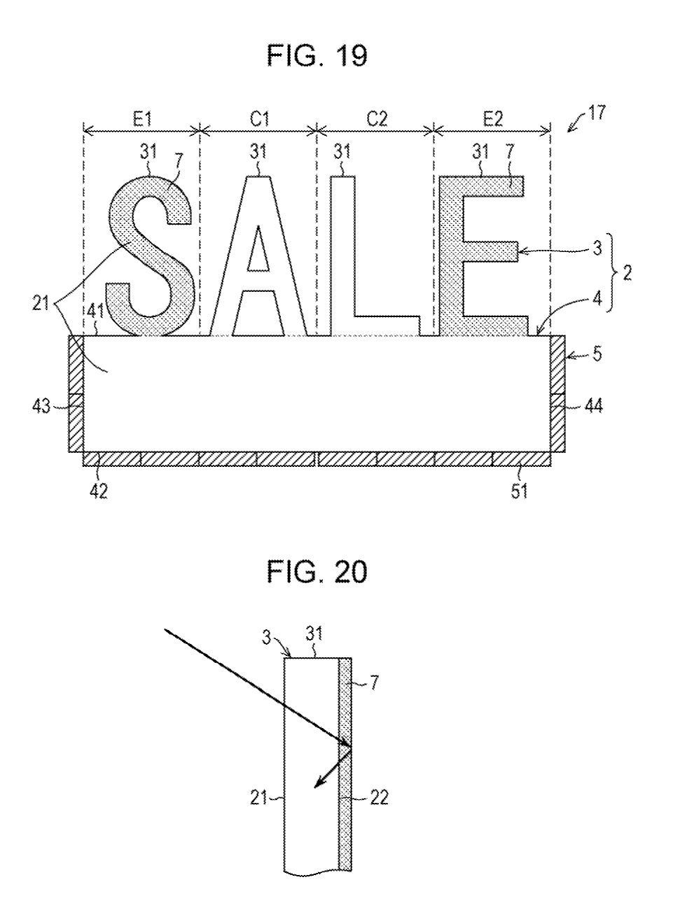

Another embodiment of the invention will be described as follows on the basis of FIG. 19 to FIG. 21. Note that, for convenience of description, the same reference signs are assigned to members having the same functions as those of the members described in the aforementioned embodiments, and description thereof is omitted.

### (Configuration of Fluorescent Concentrator Solar Cell 17)

A fluorescent concentrator solar cell 17 according to the present embodiment is different from the fluorescent concentrator solar cell 11 according to Embodiment 1 in that a rear surface reflecting layer 7 is provided in a part of the rear surface 22 of the display portion 3.

FIG. 19 is a front view illustrating the fluorescent concentrator solar cell 17 according to the present embodiment. As illustrated in FIG. 19, the fluorescent concentrator solar cell 17 includes the fluorescent concentrating plate 2, the solar cell array 5, and the rear surface reflecting layer (second reflecting member) 7.

### (Rear Surface Reflecting Layer 7)

The rear surface reflecting layer 7 is a reflecting member that is provided in the rear surface 22 of the fluorescent concentrating plate 2 and reflects light emitted from the rear surface 22 to the rear surface 22. In the present embodiment, in the display portion 3 constituted by the four letters of “S”, “A”, “L”, and “E”, the rear surface reflecting layer 7 is provided in parts of the rear surface 22 of the display portion 3, which correspond to “S” and “E” that are positioned at the both ends. In other words, the rear surface reflecting layer 7 is provided in the parts of the rear surface 22 of the display portion 3, which correspond to “S” and “E” connected to the both end parts E1 and E2 of the base portion 4.

FIG. 20 is a side view illustrating a reflecting action of the rear surface reflecting layer 7. As illustrated in FIG. 20, by providing the rear surface reflecting layer 7 in the rear surface 22 of the display portion 3, it is possible to reflect light, which is incident from the front surface 21 and is not absorbed by a phosphor and is emitted from the rear surface 22 as it is, by the rear surface reflecting layer 7 and return it to the display portion 3. Thereby, light quantity absorbed by the phosphor is increased, so that it is possible to increase light quantity propagated to the base portion 4 from the display portion 3.

Moreover, since the light quantity propagated to the base portion 4 from the display portion 3 is increased, light quantity used for power generation by the solar cell array 5 is also increased. Thus, it is possible to increase power generation quantity which is able to be taken out from the entire fluorescent concentrator solar cell 17.

Examples of the rear surface reflecting layer 7 include a metal thin film (aluminum, silver, titanium, chromium, or the like), reflective ink (reflective paint or the like), and a derivative multilayer film (for example, a laminated film, a laminated deposition film, or the like) that selectively reflects light in a predetermined wavelength region.

For example, in a case where the phosphor included in the fluorescent concentrating plate 2 is a red phosphor, by using the rear surface reflecting layer 7 that selectively reflects light in a wavelength region from blue to green, it is possible to improve the power generation quantity of the fluorescent concentrator solar cell 17.

### (Effect of Fluorescent Concentrator Solar Cell 17)

As above, by providing the rear surface reflecting layer 7 in the parts of the rear surface 22 of the display portion 3, which correspond to “S” and “E” connected to the both end parts E1 and E2 of the base portion 4, it is possible to return light, which is to be emitted from the rear surface 22, to the display portion 3 for reuse. Thus, it is possible to make light quantity propagated to the both end parts E1 and E2 of the base portion 4 from the parts of the display portion 3, which correspond to “S” and “E”, relatively large compared with light quantity propagated to the center parts C1 and C2 of the base portion 4 from the parts of the display portion 3, which correspond to “A” and “L”.

Accordingly, since the light quantity distribution (refer to FIG. 9(a)) of the light propagated to the upper end surface 41 of the base portion 4 from the display portion 3 and the light quantity distribution (refer to FIG. 9(b)) of the light guided to the lower end surface 42 and the side end surfaces 43 and 44 from the upper end surface 41 by the base portion 4 having the rectangular shape complement each other, ununiformity of light receiving quantity among the solar cells 51 is improved, so that it is possible to equalize the light receiving quantity.

Moreover, since the light quantity propagated to the base portion 4 from the display portion 3 is increased, the light quantity used for power generation by the solar cell array 5 is also increased. Thus, it is possible to increase the power generation quantity which is able to be taken out from the entire fluorescent concentrator solar cell 17.

### Modified Example

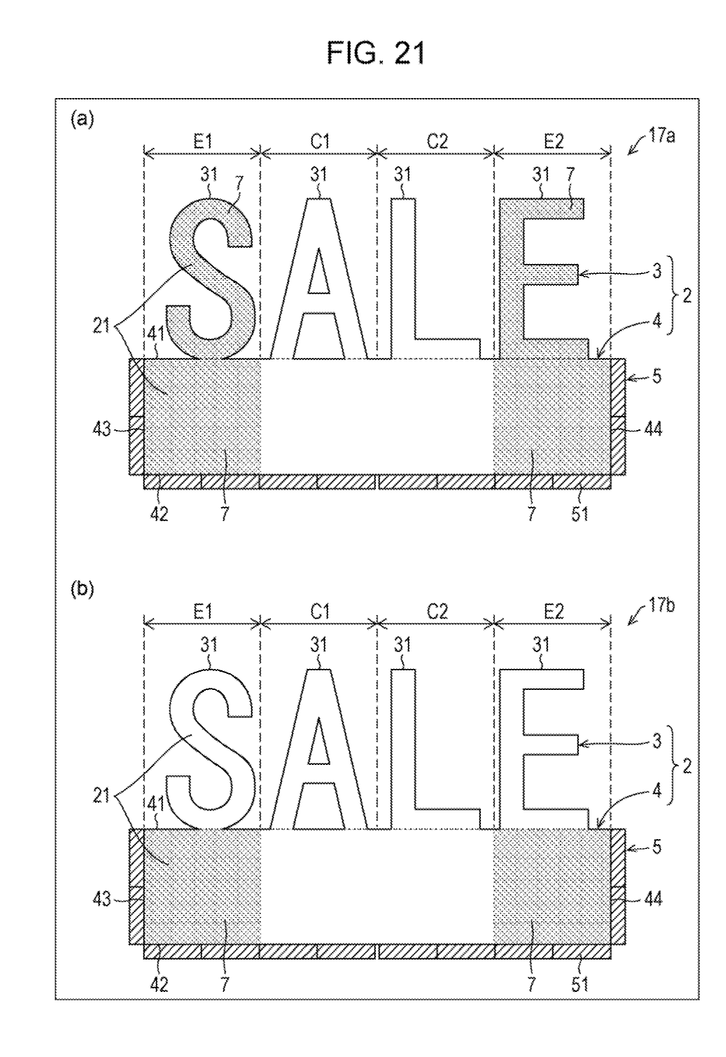

FIGS. 21(a) and (b) are front views each illustrating a modified example of the fluorescent concentrator solar cell 17. As a fluorescent concentrator solar cell 17a illustrated in FIG. 21(a), the rear surface reflecting layer 7 may be further provided in parts of the rear surface 22, which correspond to the both end parts E1 and E2 of the base portion 4, in addition to the parts of the rear surface 22 of the display portion 3, which correspond to “S” and “E” connected to the both end parts E1 and E2 of the base portion 4.

Thereby, it is possible to return light, which is to be emitted from the parts of the rear surface 22, which correspond to the both end parts E1 and E2 of the base portion 4, to the base portion 4 to perform conversion for reuse.

Accordingly, since it becomes possible to concentrate much light to the solar cells 51 arranged on the both end parts E1 and E2 of the base portion 4a, ununiformity of light receiving quantity among the solar cells 51 is improved, so that it is possible to equalize the light receiving quantity.

Moreover, as a fluorescent concentrator solar cell 17b illustrated in FIG. 21(b), the rear surface reflecting layer 7 may be provided in the parts of the rear surface 22, which correspond to the both end parts E1 and E2 of the base portion 4, instead of the parts of the rear surface 22 of the display portion 3, which correspond to “S” and “E” connected to the both end parts E1 and E2 of the base portion 4.

Also in this case, it is possible to return light, which is to be emitted from the parts of the rear surface 22, which correspond to the both end parts E1 and E2 of the base portion 4, to the base portion 4 for reuse.

Accordingly, since it becomes possible to concentrate much light to the solar cells 51 arranged on the both end parts E1 and E2 of the base portion 4, ununiformity of light receiving quantity among the solar cells 51 is improved, so that it is possible to equalize the light receiving quantity.

### Embodiment 8

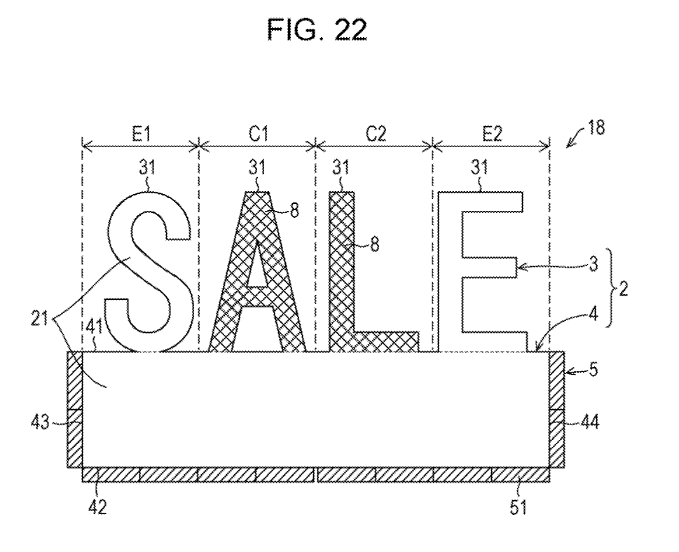

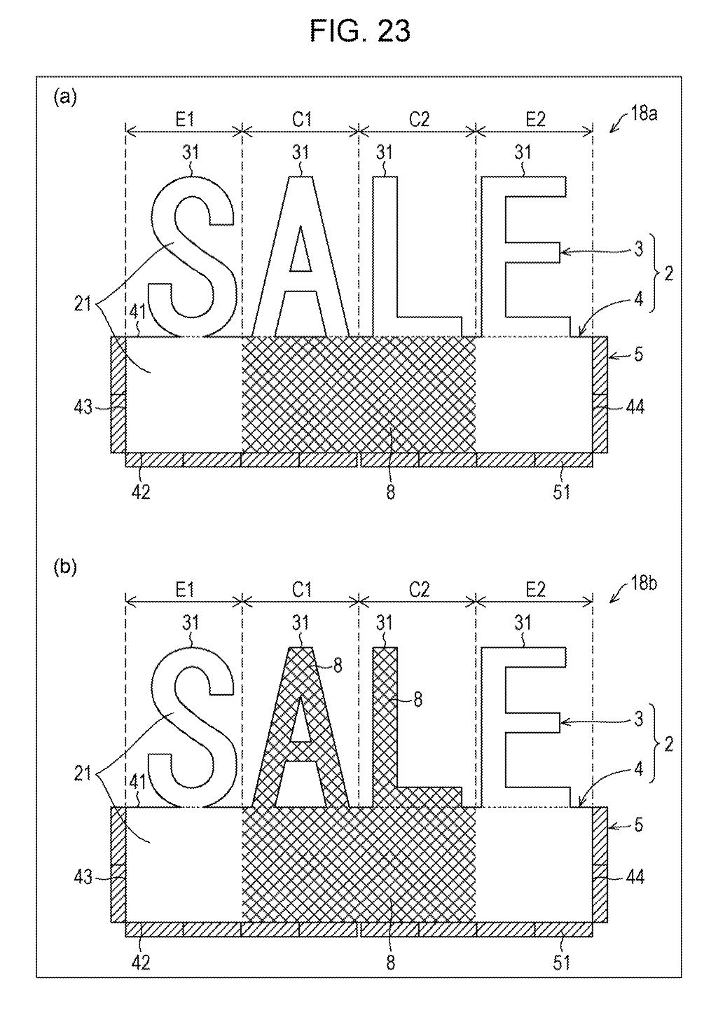

Another embodiment of the invention will be described as follows on the basis of FIG. 22 and FIG. 23. Note that, for convenience of description, the same reference signs are assigned to members having the same functions as those of the members described in the aforementioned embodiments, and description thereof is omitted.

### (Configuration of Fluorescent Concentrator Solar Cell 18)

A fluorescent concentrator solar cell 18 according to the present embodiment is different from the fluorescent concentrator solar cell 11 according to Embodiment 1 in that a color filter 8 is provided in a part of the front surface 21 of the display portion 3.

FIG. 22 is a front view illustrating the fluorescent concentrator solar cell 18 according to the present embodiment. As illustrated in FIG. 22, the fluorescent concentrator solar cell 18 includes the fluorescent concentrating plate 2, the solar cell array 5, and the color filter 8.

### (Color Filter 8)

The color filter 8 is a filter that is provided in a part of the front surface 21 of the fluorescent concentrating plate 2 and has a selective transmission property by which light in a predetermined wavelength region is selectively transmitted. In the present embodiment, in the display portion 3 constituted by the four letters of “S”, “A”, “L”, and “E”, the color filter 8 is provided in parts of the front surface 21, which correspond to “A” and “L” arranged between “S” and “E” that are positioned at the both ends. In other words, the color filter 8 is provided in the parts of the front surface 21 of the display portion 3, which correspond to “A” and “L” connected to the center parts C1 and C2 of the base portion 4.

By providing the color filter 8 in the parts of the front surface 21 of the display portion 3, which correspond to “A” and “L”, light attenuated by the color filter 8 is incident on the parts of the display portion 3, which correspond to “A” and “L”. Therefore, light quantity incident from the parts of the front surface 21 of the display portion 3, which correspond to “A” and “L”, is relatively small compared with light quantity incident from parts of the front surface 21 of the display portion 3, which correspond to “S” and “E”.

Examples of the color filter 8 include a derivative multilayer film (for example, a laminated film, a laminated deposition film, or the like) that selectively transmits light in a predetermined wavelength region.

### (Effect of Fluorescent Concentrator Solar Cell 18)

As above, in the display portion 3 constituted by the four letters of “S”, “A”, “L”, and “E”, by providing the color filter 8 in the parts of the front surface 21 of the display portion 3, which correspond to “A” and “L”, it is possible to display “S” and “E” and “A” and “L” with different colors. Thus, it is possible to improve a visual effect by the display portion 3.

Moreover, by providing the color filter 8 in the parts of the front surface 21 of the display portion 3, which correspond to “A” and “L”, the light attenuated by the color filter 8 is incident on the parts of the display portion 3, which correspond to “A” and “L”. Thus, the light quantity incident from the parts of the front surface 21 of the display portion 3, which correspond to “A” and “L”, is relatively small compared with the light quantity incident from the parts of the front surface 21 of the display portion 3, which correspond to “S” and “E”.

Therefore, it is possible to make light quantity propagated to the center parts C1 and C2 of the base portion 4 from the parts of the display portion 3, which correspond to “A” and “L”, relatively small compared with light quantity propagated to the both end parts E1 and E2 of the base portion 4 from the parts of the display portion 3, which correspond to “S” and “E”.

Accordingly, since the light quantity distribution (refer to FIG. 9(a)) of the light propagated to the upper end surface 41 of the base portion 4 from the display portion 3 and the light quantity distribution (refer to FIG. 9(b)) of the light guided to the lower end surface 42 and the side end surfaces 43 and 44 from the upper end surface 41 by the base portion 4 having the rectangular shape complement each other, ununiformity of light receiving quantity among the solar cells 51 is improved, so that it is possible to equalize the light receiving quantity.

### Modified Example

FIGS. 23(a) and (b) are front views each illustrating a modified example of the fluorescent concentrator solar cell 18. As a fluorescent concentrator solar cell 18a illustrated in FIG. 23(a), the color filter 8 may be provided in the parts of the front surface 21, which correspond to the both end parts E1 and E2 of the base portion 4, instead of the parts of the front surface 21 of the display portion 3, which correspond to “S” and “E” connected to the both end parts E1 and E2 of the base portion 4.

Also in this case, light incident from the parts of the front surface 21, which correspond to the center parts C1 and C2 of the base portion 4, is attenuated, so that it is possible to reduce light quantity concentrated to the solar cells 51 arranged on parts of the lower end surface 42, which correspond to the center parts C1 and C2 of the base portion 4.

Accordingly, by providing the color filter 8 in the parts of the front surface 21, which correspond to the both end parts E1 and E2 of the base portion 4, ununiformity of light receiving quantity among the solar cells 51 is improved, so that it is possible to equalize the light receiving quantity.

Moreover, as a fluorescent concentrator solar cell 18b illustrated in FIG. 23(b), the color filter 8 may be further provided in the parts of the front surface 21, which correspond to the center parts C1 and C2 of the base portion 4, in addition to the parts of the front surface 21 of the display portion 3, which correspond to “A” and “E” connected to the center parts C1 and C2 of the base portion 4.

Thereby, the light incident from the parts of the front surface 21, which correspond to the center parts C1 and C2 of the base portion 4, is attenuated, so that it is possible to reduce the light quantity concentrated to the solar cells 51 arranged on the parts of the lower end surface 42, which correspond to the center parts C1 and C2 of the base portion 4.

Accordingly, by providing the color filter 8 in the parts of the front surface 21, which correspond to the center parts C1 and C2 of the base portion 4, in addition to the parts of the front surface 21 of the display portion 3, which correspond to “A” and “E” connected to the center parts C1 and C2 of the base portion 4, ununiformity of light receiving quantity among the solar cells 51 is improved more effectively, so that it is possible to equalize the light receiving quantity.

### CONCLUSION

A fluorescent concentrator solar cell according to an aspect 1 of the invention includes: a fluorescent concentrating plate that includes a phosphor converting a wavelength of received light and guides the light; and a solar cell (solar cell array 5) that includes a plurality of solar cells each of which receives the light guided by the fluorescent concentrating plate, in which the fluorescent concentrating plate includes a display portion that includes a first end surface (peripheral end surface 31) which emits a part of the guided light to an outside to thereby perform light emission and that is formed in an arbitrary shape, and a base portion that includes a second end surface (upper end surface 41) which supports the display portion and a third end surface (lower end surface 42, side end surfaces 43 and 44) on which the solar cell is arranged.

In the aforementioned configuration, the display portion formed in the arbitrary shape (of a letter, a figure, a symbol, or the like, for example) is designed to emit a part of the guided light to the outside from the first end surface to thereby perform light emission. It is therefore possible to emit light from a contour part of the display portion formed in the arbitrary shape, thus making it possible to obtain a high visual effect, which has not achieved before, by using the fluorescent concentrating plate.

Moreover, in the aforementioned configuration, since the fluorescent concentrating plate itself functions as the display portion formed in the arbitrary shape such as a letter, a figure, or a symbol and receiving and guiding light, it is possible to restrict the display portion to shut out light. Furthermore, light which is guided in the display portion but is not emitted to the outside from the first end surface is propagated to the base portion from the second end surface of the base portion, guided in the inside of the base portion, and concentrated to the solar cell which are arranged on the third end surface. At this time, the light propagated to the base portion from the display portion is scattered during the light guiding process to reach the third end surface from the second end surface of the base portion, so that ununiformity of light receiving quantity among the solar cells is improved and equalized. Thus, it is possible to suppress occurrence of variation in electric current values generated by the solar cells.

Accordingly, with the aforementioned configuration, it is possible to realize the fluorescent concentrator solar cell by which a high visual effect which has not achieved before is obtained by using the fluorescent concentrating plate while suppressing variation in electric current values among the solar cells.

In a fluorescent concentrator solar cell according to an aspect 2 of the invention, a shape of each of the display portion and the base portion may be set so that light quantity distribution of the light guided to the second end surface by the display portion and light quantity distribution of the light guided to the third end surface from the second end surface by the base portion complement each other, in the aspect 1.

With the aforementioned configuration, since the light quantity distribution of the light guided to the second end surface by the display portion and light quantity distribution of the light guided to the third end surface from the second end surface by the base portion complement each other, ununiformity of light receiving quantity among the solar cells arranged on the third end surface is improved, so that it is possible to equalize the light receiving quantity.

In a fluorescent concentrator solar cell according to an aspect 3 of the invention, a total surface area of the first end surface may be large compared with a total surface area of the third end surface, in the aspect 1 or 2.

With the aforementioned configuration, it is possible to reduce a difference between a maximum value and a minimum value of light quantity received by the solar cell, thus making it possible to improve ununiformity of light receiving quantity among the solar cells.

Accordingly, with the aforementioned configuration, it is possible to suitably suppress variation in electric current values among the solar cells.

Moreover, with the aforementioned configuration, light quantity of light emitted to the outside from the first end surface of the display portion becomes relatively large, so that it is possible to obtain a high visual effect, for example, in a case where the display portion is used for POP advertisement or the like.

In a fluorescent concentrator solar cell according to an aspect 4 of the invention, in the aspects 1 to 3, in a case of being viewed from a thickness direction of the fluorescent concentrating plate, the second end surface and the third end surface may be substantially parallel, and a mathematical relation of 1≤H1/H0≤4 may be satisfied, in a case where a width of the display portion in a perpendicular direction of the second end surface and a distance between the second end surface and the third end surface are defined as H1 and H0, respectively.

In a case of H1/H0<1, an output of the solar cell is greatly lowered. Moreover, in a case of H1/H0>4, the difference between the maximum value and the minimum value of light received by the solar cells becomes large, so that variation in light receiving quantity among the solar cells is increased.

Accordingly, by satisfying the mathematical relation of 1≤H1/H0≤4, it is possible to suitably suppress variation in electric current values among the solar cells, and to suitably reduce a power loss in the solar cell.

In a fluorescent concentrator solar cell according to an aspect 5 of the invention, in the aspects 1 to 3, the fluorescent concentrating plate may include a front surface which intersects with the first end surface, the second end surface, and the third end surface, and a rear surface opposed to the front surface, each of three or more parts of the display portion may be supported by the second end surface, and, in the case of being viewed form the thickness direction of the fluorescent concentrating plate, a surface area of parts of the front surface of the display portion, which are positioned at both ends in the display portion, may be large compared with a surface area of a part of the front surface of the display portion, which is positioned between the parts of the display portion.

With the aforementioned configuration, it is possible to make light quantity propagated to the base portion from the parts of the display portion, which are positioned at the both ends, relatively large compared with light quantity propagated to the base portion from the part of the display portion, which is positioned between the parts of the display portion.

Accordingly, with the aforementioned configuration, by changing light quantity distribution of light propagated to the base portion from the display portion to thereby compensate for light quantity which is relatively insufficient in a vicinity of each of the both ends of the base portion, it is possible to improve ununiformity of light receiving quantity among the solar cells.

In a fluorescent concentrator solar cell according to an aspect 6 of the invention, in the aspects 1 to 3, in the case of being viewed from the thickness direction of the fluorescent concentrating plate, a distance between the second end surface and the third end surface which face each other may be changed.

With the aforementioned configuration, it is possible to partially change light receiving quantity of the base portion in accordance with the distance between the second end surface and the third end surface, so that it is possible to improve ununiformity of light receiving quantity among the solar cells by changing light quantity distribution of light guided to the third end surface by the base portion.

Particularly, in order to contribute to equalization of the light quantity distribution of the light guided to the third end surface, it is preferable that the configuration of the aspect 6 is applied to the configuration of the aspect 2.

In a fluorescent concentrator solar cell according to an aspect 7 of the invention, in the aspect 6, the distance in each of both end parts of the second end surface may be long compared with the distance in a center part of the second end surface, which is positioned between the both end parts.

With the aforementioned configuration, it is possible to make light receiving quantity of the base portion in the both end parts relatively large compared with light receiving quantity of the base portion in the center part, so that it is possible to increase light quantity distribution of light guided to both end parts of the third end surface by the base portion.

In a fluorescent concentrator solar cell according to an aspect 8 of the invention, in the aspect 6, the fluorescent concentrating plate may include a front surface which intersects with the first end surface, the second end surface, and the third end surface, and a rear surface opposed to the front surface, each of a plurality of parts of the display portion may be supported by the second end surface, the distance may be gradually reduced as, from one end part of the second end surface, coming closer to the other end surface, and, in the display portion, a surface area of the front surface of each part of the display portion may be gradually increased as, from the one end part of the second end surface, coming closer to the other end part.

With the aforementioned configuration, light quantity of light propagated to the base portion from the display portion is gradually increased as, from the one end part of the second end surface, coming to the other end part. On the other hand, light quantity received by the base portion with the front surface and the rear surface is gradually reduced as, from the one end part of the second end surface, coming closer to the other end part.

Accordingly, with the aforementioned configuration, since light quantity distribution of light propagated to the base portion from the display portion and light quantity distribution of light guided to the third end surface by the base portion complement each other, ununiformity of light receiving quantity among the solar cells is improved, so that it is possible to equalize the light receiving quantity.

In a fluorescent concentrator solar cell according to an aspect 9 of the invention, in the aspects 1 to 8, the first end surface may be inclined with respect to the thickness direction of the fluorescent concentrating plate.

In the aforementioned configuration, the first end surface of the display portion is inclined with respect to the thickness direction of the fluorescent concentrating plate, so that a surface area of the first end surface is relatively large compared with that of the first end surface parallel to the thickness direction of the fluorescent concentrating plate. Thereby, it is possible to emit more light to the outside from the first end surface of the display portion.

Accordingly, with the aforementioned configuration, a contour part of the display portion is observed more remarkably, so that it is possible to enhance a visual effect of the display portion.

In a fluorescent concentrator solar cell according to an aspect 10 of the invention, in the aspects 1 to 9, minute roughness may be formed on the first end surface.

With the aforementioned configuration, since the minute roughness is formed on the first end surface of the display portion, a surface area of the first end surface is relatively large compared with that of the first end surface which is flat. Thereby, it is possible to emit more light to the outside from the first end surface of the display portion.

Accordingly, with the aforementioned configuration, a contour part of the display portion is observed more remarkably, so that it is possible to enhance a visual effect of the display portion.

A fluorescent concentrator solar cell according to an aspect 11 of the invention may further include, in the aspects 1 to 10, a first reflecting member (reflecting layer 6) that reflects a part of the light, which is emitted from the first end surface, to the first end surface.

With the aforementioned configuration, the first reflecting member restricts light to be emitted to the outside from the first end surface of the display portion, so that it is possible to increase light quantity propagated to the base portion from the display portion.

Accordingly, with the aforementioned configuration, light quantity used for power generation by the solar cell arranged on the third end surface of the base portion is increased, so that it is possible to increase power generation quantity which is able to be taken out from the entire fluorescent concentrator solar cell.

Particularly, in order for the first reflecting member to contribute to equalization of the light quantity distribution of the light guided to the third end surface, it is preferable that the configuration of the aspect 11 is applied to the configuration of the aspect 2. For example, by providing the first reflecting member in a part of a letter, a figure, a symbol, or the like, which is positioned at each of both ends of the display portion, it is possible to equalize the light quantity distribution of the light guided to the third end surface more.

In a fluorescent concentrator solar cell according to an aspect 12 of the invention, in the aspect 11, the first reflecting member may reflects light in a predetermined wavelength region selectively from the light emitted from the first end surface.

With the aforementioned configuration, it is possible to cause the first end surface of the display portion to emit light of any color, thus making it possible to improve design of the display portion. Moreover, it is possible to selectively reflect light in a predetermined wavelength region, which is guided in an inside of the display portion, and propagate it to the base portion to use it for power generation by the solar cell.

In a fluorescent concentrator solar cell according to an aspect 13 of the invention, in the aspect 11 or 12, the first reflecting member may be provided in a part of the first end surface.

With the aforementioned configuration, by selectively providing the first reflecting member in a part of the first end surface, it is possible to change the light quantity distribution of the light propagated to the base portion from the display portion.

Particularly, in order for the first reflecting member to contribute to equalization of the light quantity distribution of the light guided to the third end surface, it is preferable that the configuration of the aspect 13 is applied to the configuration of the aspect 2.

In a fluorescent concentrator solar cell according to an aspect 14 of the invention, in the aspects 1 to 13, the fluorescent concentrating plate may include the front surface which intersects with the first end surface, the second end surface, and the third end surface, and the rear surface opposed to the front surface, and further include a second reflecting member (rear surface reflecting layer 7) that is provided in a part of the rear surface and reflects the light, which is emitted from the rear surface, to the rear surface.

With the aforementioned configuration, it is possible to reflect light, which is incident from the front surface of the fluorescent concentrating plate (the display portion and the based portion) and is not absorbed by a phosphor and is emitted from the rear surface as it is, by the second reflecting member and return it to the fluorescent concentrating plate.

Accordingly, with the aforementioned configuration, light emitted from the rear surface of the fluorescent concentrating plate is able to be reused, thus making it possible to increase the light quantity used for power generation in the solar cell.

Moreover, with the aforementioned configuration, by selectively providing the second reflecting member in a part of the rear surface in the display portion or the base portion, it is possible to change the light quantity distribution of the light guided to the second end surface by the display portion or light quantity distribution of light guided to the third end surface from the rear surface by the base portion. In this case, particularly, in order to contribute to equalization of the light quantity distribution of the light guided to the third end surface, it is preferable that the configuration of the aspect 14 is applied to the configuration of the aspect 2.

In a fluorescent concentrator solar cell according to an aspect 15 of the invention, in the aspects 1 to 14, the fluorescent concentrating plate may include the front surface which intersects with the first end surface, the second end surface, and the third end surface, and the rear surface opposed to the front surface, and further include a color filter that is provided in a part of the front surface and selectively transmits the light in the predetermined wavelength region.

With the aforementioned configuration, for example, by providing the color filter on the front surface of the display portion, it is possible to display a part of the display portion with a different color, thus making it possible to improve a visual effect of the display portion.

Moreover, with the aforementioned configuration, since light attenuated by the color filter is incident on the front surface of the fluorescent concentrating plate, by selectively providing the color filter in a part of the front surface of the display portion or the base portion, it is possible to change light quantity distribution of light propagated to the second end surface from the display portion or light quantity distribution of light guided to the third end surface by the base portion. In this case, particularly, in order to contribute to equalization of the light quantity distribution of the light guided to the third end surface, it is preferable that the configuration of the aspect 15 is applied to the configuration of the aspect 2.

### [Additional Note]

The invention is not limited to each of the embodiments described above, and may be modified in various manners within the scope described in the claims and an embodiment achieved by appropriately combining technical means disclosed in each of different embodiments is also encompassed in the technical scope of the invention. Further, by combining the technical means disclosed in each of the embodiments, a new technical feature may be formed.

### [Supplementary Note]

Note that, the invention is able to be described also as follows. That is, a fluorescent concentrator solar cell according to the invention is a fluorescent concentrator solar cell a region of which is divided into a display portion in which a fluorescent concentrating plate is processed into a shape of a letter or a logotype and on which a solar cell is not arranged and a base portion on which the solar cell is arranged, in which a side surface of the display portion is processed so as to emit light concentrated by the fluorescent concentrating plate to an outside.

Moreover, in the fluorescent concentrator solar cell according to the invention, the fluorescent concentrator solar cell includes the display portion in which the fluorescent concentrating plate is processed into a shape of a letter or a logotype and on which the solar cell is not arranged and the base portion on which the solar cell is arranged, in which a total length of the side surface of the display portion may be long compared with a total length of a side surface of the base portion.

Moreover, in the fluorescent concentrator solar cell according to the invention, in a case where a size (height) of a letter is set to be H1, a height H0 of the base portion may satisfy ¼H1≤H0≤H1.

Moreover, in the fluorescent concentrator solar cell according to the invention, the side surface of the display portion is processed so as to emit light.

Moreover, in the fluorescent concentrator solar cell according to the invention, sizes of letters of the display portion may vary.

Moreover, in the fluorescent concentrator solar cell according to the invention, a size of the base portion may vary.

Moreover, in the fluorescent concentrator solar cell according to the invention, a reflecting plate may be selectively arranged in a part of a letter portion or the base portion.

### INDUSTRIAL APPLICABILITY

The invention is able to be used as a fluorescent concentrator solar cell that includes a fluorescent concentrating plate, and, particularly, able to be suitably used for POP advertisement that advertises a product or the like.

### REFERENCE SIGNS LIST

2 fluorescent concentrating plate
3, 3a, 3b display portion
4, 4a, 4b, 4c base portion
6 reflecting layer (first reflecting member)
7 rear surface reflecting layer (second reflecting member)
11 to 18, 17a, 17b, 18a, 18b fluorescent concentrator solar cell
21 front surface (light-receiving surface)
22 rear surface (light-receiving surface, facing surface)
31, 31a, 31b peripheral end surface (first end surface)
41 upper end surface (second end surface)
42 lower end surface (third end surface)
43, 44 side end surface (third end surface)
H0 height (distance)
H1 height (width)

1. A fluorescent concentrator solar cell, comprising:
a fluorescent concentrating plate that includes a phosphor converting a wavelength of received light and guides the light; and
a solar cell that includes a plurality of solar cells each of which receives the light guided by the fluorescent concentrating plate, wherein
the fluorescent concentrating plate includes
a display portion that includes a first end surface which emits a part of the guided light to an outside to thereby perform light emission and that is formed in an arbitrary shape, and
a base portion that includes a second end surface which supports the display portion and a third end surface on which the solar cell is arranged.

2. The fluorescent concentrator solar cell according to claim 1, wherein a shape of each of the display portion and the base portion is set so that light quantity distribution of the light guided to the second end surface by the display portion and light quantity distribution of the light guided to the third end surface from the second end surface by the base portion complement each other.

3. The fluorescent concentrator solar cell according to claim 1, wherein a total surface area of the first end surface is large compared with a total surface area of the third end surface.

4. The fluorescent concentrator solar cell according to claim 1, wherein,
in a case of being viewed from a thickness direction of the fluorescent concentrating plate,
the second end surface and the third end surface are substantially parallel, and
a mathematical relation of 1≤H1/H0≤4 is satisfied,
in a case where a width of the display portion in a perpendicular direction of the second end surface and a distance between the second end surface and the third end surface are defined as H1 and H0, respectively.

5. The fluorescent concentrator solar cell according to claim 1, wherein the first end surface is inclined with respect to the thickness direction of the fluorescent concentrating plate.
